(19) United States
(12) Patent Application Publication
(10) Pub. No.: US 2026/0143820 A1
(43) Pub. Date: May 21, 2026

(54) SEMICONDUCTOR DIODE STRUCTURE AND METHOD FOR FORMING THE SAME

(71) Applicant: TAIWAN SEMICONDUCTOR MANUFACTURING COMPANY, LTD., Hsinchu (TW)

(72) Inventors: Tao-Yi HUNG, Hsinchu (TW); Wun-Jie LIN, Hsinchu (TW); Jam-Wem LEE, Hsinchu (TW); Kuo-Ji CHEN, Hsinchu (TW)

(21) Appl. No.: 19/077,397

(22) Filed: Mar. 12, 2025

Related U.S. Application Data
(60) Provisional application No. 63/723,169, filed on Nov. 21, 2024.

(51) Int. Cl. H10D 89/60; H01L 23/528; H10D 12/00; H10D 12/01; H10D 62/10; H10D 62/60; H10D 64/01; H10D 64/27; H10D 84/82

(52) U.S. Cl. CPC H10D 89/611; H10D 12/021; H10D 12/212; H10D 62/115; H10D 62/121; H10D 62/123; H10D 62/124; H10D 62/60; H10D 64/017; H10D 64/311; H10D 89/921; H10W 20/435; H10D 84/82

(57) ABSTRACT

A semiconductor diode structure includes a semiconductor layer, a first p-type doped structure disposed over the semiconductor layer, a first n-type doped structure over the semiconductor layer, a central structure disposed between the first p-type doped structure and the first n-type doped structure, a second p-type doped structure disposed between the first p-type doped structure and the central structure, and a second n-type doped structure disposed between the first n-type doped structure and the central structure. The first and second p-type doped structures are line symmetric to the second and first n-type doped structures about the central structure.

### PRIORITY DATA

This patent claims the benefit of U.S. Provisional Patent Application Ser. No. 63/723,169 filed Nov. 21, 2024, the entire disclosure of which is hereby incorporated by reference.

### BACKGROUND

In a semiconductor integrated circuit (IC), electrostatic discharge (ESD) may result in damage to a semiconductor device. To reduce the risk of such damage, protection circuits are provided in the ICs for rendering a safe discharge path. The protection circuit is basically a switch which is off during normal circuit operation and turns on during an ESD event, when a high voltage is present. Accordingly, ESD protection helps to protect the ICs from damage.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic diagram of an ESD protection circuit in accordance with some embodiments.

FIG. 2 is a schematic top view of a semiconductor diode structure in accordance with aspects of one or more embodiments of the present disclosure.

FIG. 3 is a schematic top view of a semiconductor diode structure in accordance with aspects of one or more embodiments of the present disclosure.

FIG. 4 is a cross-sectional view of a semiconductor diode structure in accordance with aspects of one or more embodiments of the present disclosure.

FIG. 5 is a cross-sectional view of a semiconductor diode structure in accordance with aspects of one or more embodiments of the present disclosure.

FIG. 6 is a flowchart representing a method for forming a semiconductor diode structure according to some aspects of the present disclosure.

FIGS. 7A to 7S are cross-sectional views of a semiconductor diode structure at various fabrication stages constructed according to aspects of one or more embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

This description of illustrative embodiments is intended to be read in connection with the accompanying drawings, which are to be considered part of the entire written description. In the description of embodiments disclosed herein, any reference to direction or orientation is merely intended for convenience of description and is not intended in any way to limit the scope of the present disclosure. Relative terms such as “lower,” “upper,” “horizontal,” “vertical,” “above,” “below,” “up,” “down,” “top” and “bottom” as well as derivatives thereof (e.g., “horizontally,” “downwardly,” “upwardly,” etc.) should be construed to refer to the orientation as then described or as shown in the drawing under discussion. These relative terms are for convenience of description only and do not require that the apparatus be constructed or operated in a particular orientation. Terms such as “attached,” “affixed,” “connected” and “interconnected” refer to a relationship wherein structures are secured or attached to one another either directly or indirectly through intervening structures, as well as both movable or rigid attachments or relationships, unless expressly described otherwise. Moreover, the features and benefits of the disclosure are illustrated by reference to the embodiments. Accordingly, the disclosure expressly should not be limited to such embodiments illustrating some possible non-limiting combination of features that may exist alone or in other combinations of features; the scope of the disclosure being defined by the claims appended hereto.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the standard deviation found in the respective testing measurements. Also, as used herein, the terms “substantially,” “approximately” or “about” generally mean within a value or range that can be contemplated by people having ordinary skill in the art. Alternatively, the terms “substantially,” “approximately” or “about” mean within an acceptable standard error of the mean when considered by one of ordinary skill in the art. People having ordinary skill in the art can understand that the acceptable standard error may vary according to different technologies. Other than in the operating/working examples, or unless otherwise expressly specified, all of the numerical ranges, amounts, values and percentages such as those for quantities of materials, durations of times, temperatures, operating conditions, ratios of amounts, and the likes thereof disclosed herein should be understood as modified in all instances by the terms “substantially,” “approximately” or “about.” Accordingly, unless indicated to the contrary, the numerical parameters set forth in the present disclosure and attached claims are approximations that can vary as desired. At the very least, each numerical parameter should be construed in light of the number of reported significant digits and by applying ordinary rounding techniques. Ranges can be expressed herein as being from one endpoint to another endpoint or between two endpoints. All ranges disclosed herein are inclusive of the endpoints, unless specified otherwise.

The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

The term “nanostructure” refers to atomic, molecular or macromolecular particles typically having a thickness in a range of approximately 1 to 100 nanometers and a width greater than the thickness. For example, the width may be at least twice the thickness, but the disclosure is not limited thereto. Typically, novel and differentiating properties and functions of nanosheet components are observed or developed at a critical length scale of under 100 nm. In some embodiments, “nanostructure” components can also be referred to as “nano-sheet,” “nano-slab,” “nano-wire,” “nano-ring” or “multi-bridge channel” components.

The semiconductor industry is constantly striving to improve integration density and miniaturize ICs, which has led to an increased susceptibility to ESD events. As devices become smaller with reduced dielectric thicknesses and reduced dielectric breakdown voltages, ESD protection has become a greater concern in advanced semiconductor technology. ESD protection devices are therefore designed to conduct the ESD current to electrical ground, thereby protecting the integrated circuits connected thereto. For example, semiconductor diode structures are used to safeguard semiconductor devices from ESD events. Additionally, researchers are exploring bulk-less processes such as “super power rail” (SPR) technology, which involves thinning a semiconductor wafer and employing dual-side power rail devices to improve area and resistance benefits. This technology includes a power delivery network (PDN) and input-output (IO) pins on both front-side and back side interconnect structures, allowing for testing through the front-side interconnect structure when the backside interconnect structure is removed.

In some embodiments, the semiconductor diode structure of the ESD protection circuit includes body diodes formed by p-n junctions in the semiconductor device, wherein the diode has a conducting path formed in a substrate of the semiconductor device. With semiconductor devices employing bulk-less processes, a conductivity or a durability of the conducting path used by the diode is reduced in comparison with other approaches, which potentially degrades diode performance for ESD protection. Removing portions of the substrate with the bulk-less process reduces a cross-sectional area of the diode, which increases a resistance of the diode and thus also reduces the ability of the diode to conduct current.

The present disclosure provides a semiconductor diode structure and a method for forming the same. In some embodiments, the semiconductor diode structure is integrated into an SPR structure for efficiently providing power to operational components of an IC. In contrast to previous power rail structures that provide power from only one side of a substrate, the SPR structure of the present disclosure allows power to be provided from a front side and a back side of a substrate incorporating the SPR structure. In some embodiments, the semiconductor diode structure includes a semiconductor layer that serves as a current path to bias an ESD in the bulk-less process, which allows for processes such as dual-side power rails.

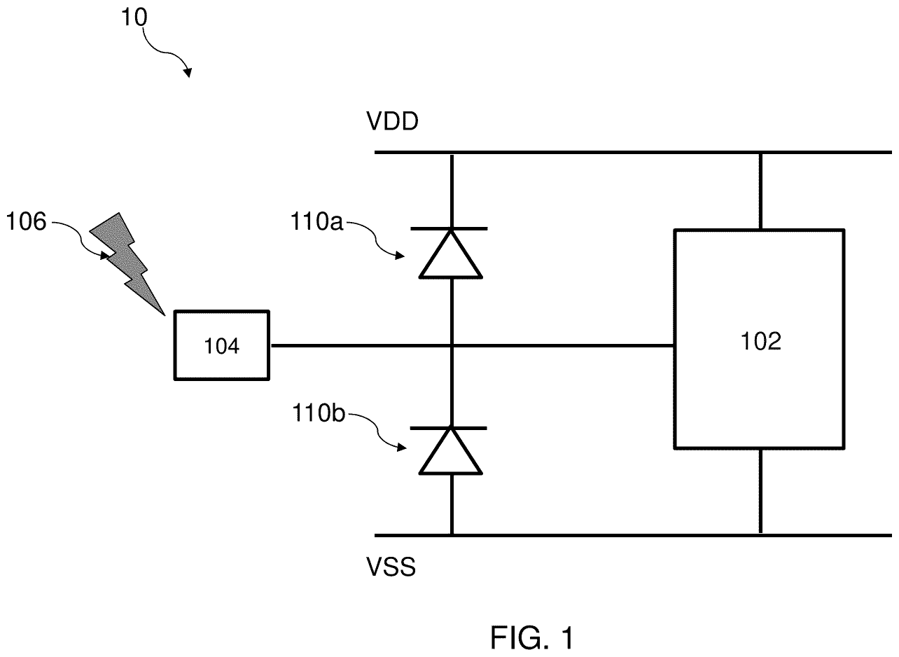

FIG. 1 is an example of an ESD protection circuit 10 in accordance with aspects of the present disclosure. The ESD protection circuit 10 is arranged to protect an internal circuit 102, which includes electronic components, from damage due to electrostatic discharge. In some embodiments, the ESD protection circuit 10 includes two semiconductor diode structures 110a and 110b, which are connected between an input/output (IO) terminal 104 and voltage terminals VDD and VSS (ground).

The internal circuit 102 is electrically connected to the IO terminal 104 and the semiconductor diode structures 110a and 110b. The internal circuit 102 is designed to receive an IO signal from the IO terminal 104, and is also connected to the voltage terminals VDD and VSS. In some embodiments, the internal circuit 102 includes at least one n-type or p-type transistor device. In some embodiments, the internal circuit 102 includes at least a logic gate cell. In some embodiments, the logic gate cell includes an AND, OR, NAND, NOR, XOR, INV, AND-OR-Invert (AOI), OR-AND-Invert (OAI), MUX, Flip-flop, BUFF, Latch, delay, or clock cell. In some embodiments, the internal circuit 102 includes at least a memory cell. In some embodiments, the memory cell includes a static random-access memory (SRAM), a dynamic random-access memory (DRAM), a resistive random-access memory (RRAM), a magnetoresistive random-access memory (MRAM) or a read-only memory (ROM). In some embodiments, the internal circuit 102 includes one or more active or passive elements. Examples of active elements include, but are not limited to, transistors and diodes. Examples of transistors include, but are not limited to, metal-oxide-semiconductor field-effect transistors (MOSFETs), complementary metal-oxide-semiconductor (CMOS) devices, bipolar junction transistors (BJT), high voltage transistors, high frequency transistors, p-channel and/or n-channel field-effect transistors (PFETs/NFETs), FinFETs, and planar MOS transistors with raised source/drain. Examples of passive elements include, but are not limited to, capacitors, inductors, fuses, and resistors.

In some embodiments, the semiconductor diode structures 110a and 110b of the ESD protection circuit 10 are body diodes formed by p-n junctions in the semiconductor structure, wherein the diode's conducting path is formed in the substrate. Under normal non-ESD conditions, a current from the IO terminal 104 flows to the internal circuit 102. During an ESD event 106, the semiconductor diode structures 110a and 110b are changed into a reverse bias condition, allowing the semiconductor diode structures 110a and 110b to safely transmit the ESD current 106 to ground VSS and prevent the internal circuit 102 from being exposed to the ESD voltage. Other ESD diode protection configurations are also covered by this disclosure.

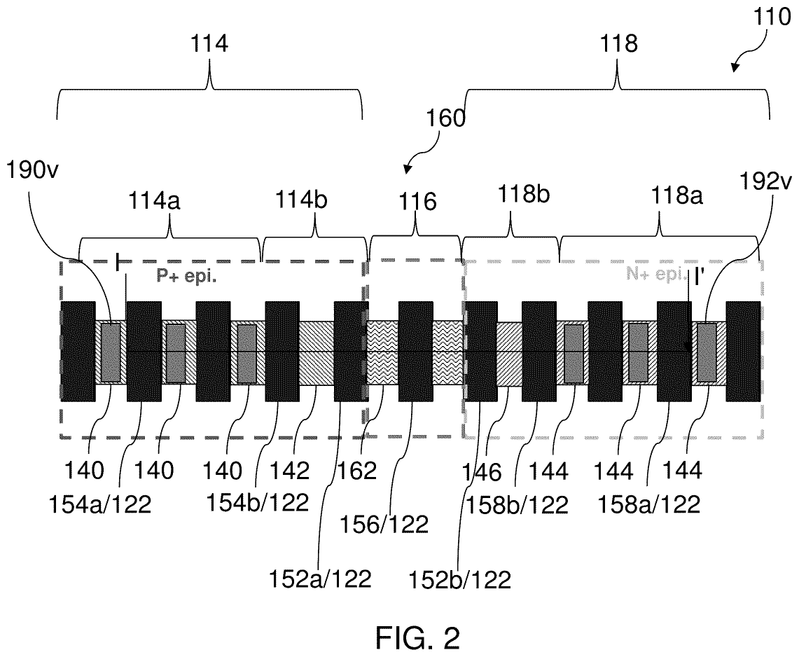

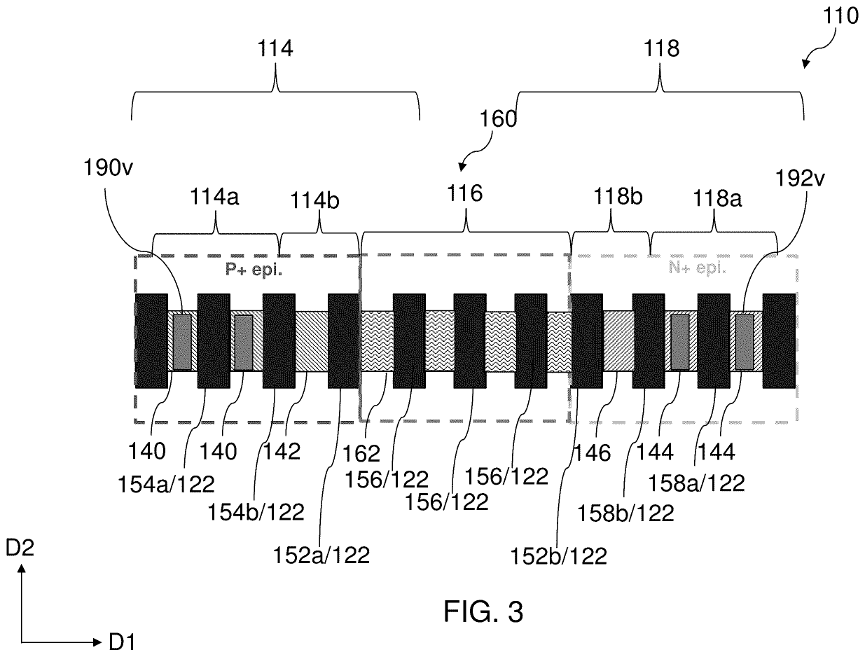

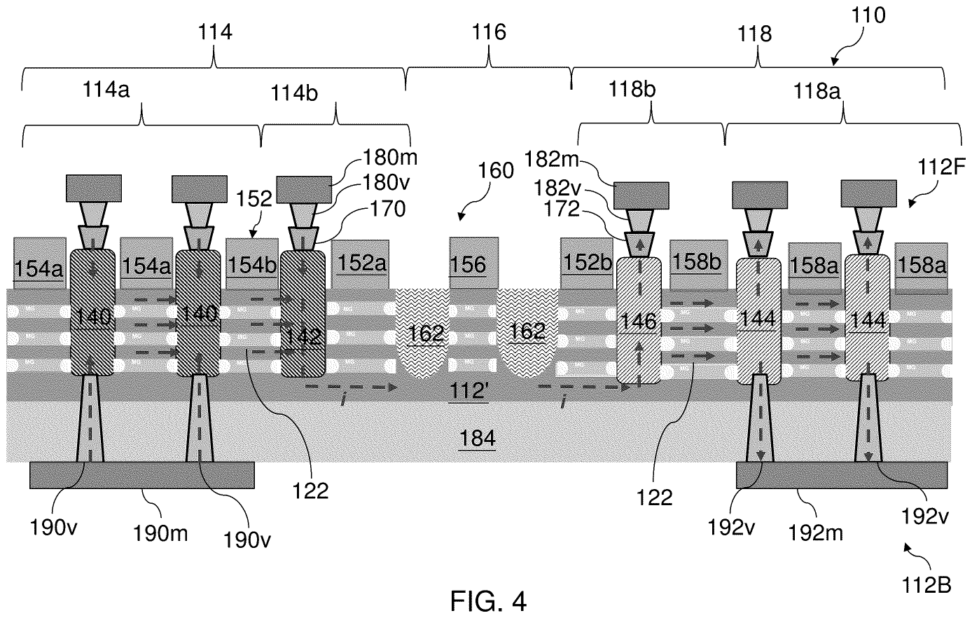

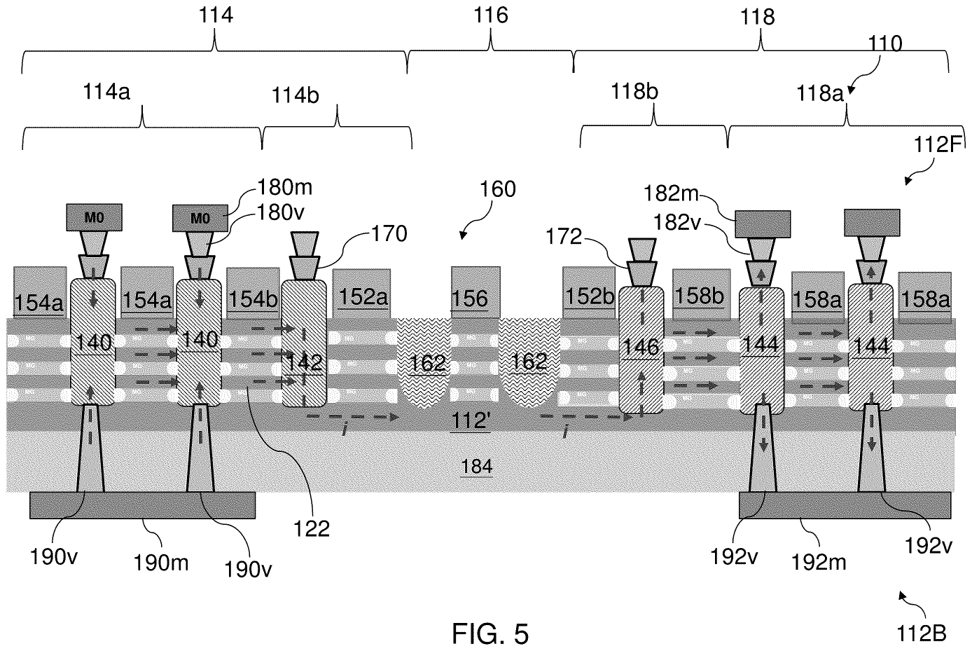

Please refer to FIGS. 2 to 5, wherein each of FIGS. 2 and 3 is a schematic top view of a semiconductor diode structure 110 in accordance with aspects of one or more embodiments of the present disclosure, and each of FIGS. 4 and 5 is a cross-sectional view of a semiconductor diode structure 110 in accordance with aspects of one or more embodiments of the present disclosure. In accordance with some embodiments, FIG. 4 is a cross-sectional view taken along line I-I′ in FIG. 2, but the disclosure is not limited thereto. In some embodiments, the semiconductor diode structure 110 may be the semiconductor diode structure 110a or 110b in the ESD protection circuit 10.

In some embodiments, the semiconductor diode structure 110 includes a semiconductor layer 112′ (shown in FIGS. 4 and 5). The semiconductor layer 112′ may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or a combination thereof. In some embodiments, isolation structures such as shallow trench isolation (STI) structures may be formed in the semiconductor layer 112′ in order to define a region where the semiconductor diode structure 110 is to be formed, although such isolation structure is not shown in FIGS. 2 to 5. In some embodiments, the semiconductor diode structure 110 includes an anode region 114, an intervening region 116 and a cathode region 118 defined over the semiconductor layer 112′. As shown in FIGS. 2 to 5, the intervening region 116 is disposed between the anode region 114 and the cathode region 118. In some embodiments, the anode region 114 may further include a VB region 114a and a VB blocking region 114b, and the cathode region 118 may further include a VB region 118a and a VB blocking region 118b. Further, the VB blocking region 114b of the anode region 114 is defined between the VB region 114a and the intervening region 116, and the VB blocking region 118b of the cathode region 118 is defined between the VB region 118a and the intervening region 116. In some embodiments, the anode region 114 (i.e., the VB region 114a and the VB blocking region 114b) and the cathode region 118 (i.e., the VB region 118a and the VB blocking region 118b) are line symmetric about the intervening region 116.

In some embodiments, the semiconductor diode structure 110 includes p-type doped structures 140 and 142 disposed over the semiconductor layer 112′ in the anode region 114 on a front side 112F of the semiconductor layer 112′. The p-type doped structures 140 are disposed in the VB region 114a of the anode region 114, while the p-type doped structure 142 is disposed in the VB blocking region 114b of the anode region 114. The p-type doped structures 140 and 142 include a same material. For example, the p-type doped structures 140 and 142 include same epitaxial materials with same p-type dopants.

In some embodiments, the semiconductor diode structure 110 includes a plurality of nanostructure channels 122 disposed between the p-type doped structure 140 in the VB region 114a and the p-type doped structure 142 in the VB blocking region 114b. In some embodiments, the nanostructure channels 122 are also disposed between adjacent p-type doped structures 140 in the VB region 114a. In some embodiments, the semiconductor diode structure 110 includes metal gates 154a and 154b disposed in the anode region 114 on the front side 112F of the semiconductor layer 112′. The metal gate 154a is disposed between the p-type doped structures 140 and wraps around the nanostructure channels 122 in the VB region 114a. The metal gate 154b is disposed between the p-type doped structure 140 in the VB region 114a and the p-type doped structure 142 in the VB blocking region 114b and wraps around the nanostructure channels 122.

In some embodiments, the semiconductor diode structure 110 includes n-type doped structures 144 and 146 disposed over the semiconductor layer 112′ in the cathode region 118 on the front side 112F of the semiconductor layer 112′. Further, the n-type doped structures 144 are disposed in the VB region 118a of the cathode region 118, while the n-type doped structure 146 is disposed in the VB blocking region 118b of the cathode region 118. The n-type doped structures 144 and 146 include a same material. For example, the n-type doped structures 144 and 146 include same epitaxial materials with same n-type dopants.

In some embodiments, the semiconductor diode structure 110 includes a plurality of nanostructure channels 122 disposed between the n-type doped structure 144 in the VB region 118a and the n-type doped structure 146 in the VB blocking region 118b. In some embodiments, the nanostructure channels 122 are also disposed between adjacent n-type doped structures 144 in the VB region 118a. In some embodiments, the semiconductor diode structure 110 includes metal gates 158a and 158b disposed in the cathode region 118 on the front side 112F of the semiconductor layer 112′. The metal gate 158a is disposed between the n-type doped structures 144, and wraps around the nanostructure channels 122 in the VB region 118a. The metal gate 158b is disposed between the n-type doped structure 144 in the VB region 118a and the n-type doped structure 146 in the VB blocking region 118b and wraps around the nanostructure channels 122.

The semiconductor diode structure 110 further includes a central structure 160 disposed in the intervening region 116. The central structure 160 is disposed between the p-type doped structures 140, 142 in the anode region 114 and the n-type doped structures 144, 146 in the cathode region 118. Further, the central structure 160 is disposed between the p-type doped structure 142 in the VB blocking region 114b and the n-type doped structure 146 in the VB blocking region 118b. Additionally, the p-type doped structure 142 is between the p-type doped structures 140 and the central structure 160, and the n-type doped structure 146 is between the n-type doped structures 144 and the central structure 160. In some embodiments, because the intervening region 116 is free of the epitaxially-grown doped structures 140, 142, 144 and 146, the intervening region 116 may be referred to as an epi-blocking region.

Referring to FIG. 4, in some embodiments, the central structure 160 includes at least a pair of isolations 162 disposed over the semiconductor layer 112′ on the front side 112F. In such embodiments, the central structure 160 includes a plurality of nanostructure channels 122 stacked over the semiconductor layer 112′ on the front side 112F, and between the pair of isolations 162. The central structure 160 further includes a metal gate 156 disposed over the semiconductor layer 112′ on the front side 112F and wraps around each of the nanostructure channels 122 between the pair of isolations 162. In such embodiments, the pair of isolations 162 are line symmetric to each other about the metal gate 156. Further, the p-type doped structures 140 and 142 are line symmetric to the n-type doped structures 144 and 146 about the central structure 160. In such line symmetric configuration, the p-type doped structures 140 and the n-type doped structures 144 are corresponding portions, and the p-type doped structure 142 and the n-type doped structure 146 are corresponding portions.

Referring to FIG. 3, in some embodiments, the central structure 160 includes a plurality of isolations 162 disposed over the semiconductor layer 112′ on the front side 112F, a plurality of nanostructure channels 122 stacked over the semiconductor layer 112′ on the front side 112F, and a plurality of metal gates 156 disposed over the semiconductor layer 112′ on the front side 112F. Each of the metal gates 156 wraps around one of the nanostructure channels 122 in a stack. In such embodiments, the isolations 162 and the metal gates 156 are alternately arranged, and the isolations 162 and the stacks of nanostructure channels 122 are also alternately arranged, as shown in FIG. 3. The central structure 160 is a line-symmetric structure. Further, the p-type doped structures 140 and 142 are line symmetric to the n-type doped structures 144 and 146 about the central structure 160. In such line symmetric configuration, the p-type doped structures 140 and the n-type doped structures 144 are corresponding portions, and the p-type doped structure 142 and the n-type doped structure 146 are corresponding portions.

In some embodiments, the semiconductor diode structure 110 includes another metal gate 152a disposed between the isolation 162 of the central structure 160 in the intervening region 116 and the p-type doped structure 142 in the VB blocking region 114b of the anode region 114, and another metal gate 152b disposed between the isolation 162 of the central structure 160 in the intervening region 116 and the n-type doped structure 146 in the VB blocking region 118b of the cathode region 118. In some embodiments, the semiconductor diode structure 110 includes additional nanostructure channels disposed over the semiconductor layer 112′ on the front side 112F. Each of the metal gates 152a and 152b wraps around the nanostructure channels 122 in a stack, as shown in FIGS. 4 and 5.

In some embodiments, the semiconductor diode structure 110 includes a plurality of MD contacts 170 and 172 disposed over the semiconductor layer 112′ on the front side 112F. The MD contacts 170 and 172 may be referred to “metal-to-drain” contacts or “metal-to-device” contacts. In some embodiments, the MD contacts 170 and 172 may be formed by a middle-end-of-line (MEOL) process. As shown in FIGS. 4 and 5, the MD contacts 170 are coupled to the p-type doped structures 140 and 142 in the anode region 114, and the MD contacts 172 are coupled to the n-type doped structures 144 and 146 in the cathode region 118.

In some embodiments, a front-side BEOL interconnect structure may be disposed over the semiconductor diode structure 110 on the front side 112F of the semiconductor layer 112′. The front-side BEOL interconnect structure may be formed through any acceptable process, such as a damascene process, a dual damascene process, or the like. The front-side BEOL interconnect structure may further include a front-side power distribution network, front-side I/O pins, and front-side power rails (e.g., VDD and VSS). Further, the front-side BEOL interconnect structure includes a plurality of conductive lines 180m and a plurality of via connectors 180v disposed in the anode region 114. The front-side BEOL interconnect structure further includes a plurality of conductive lines 182m and a plurality of via connectors 182v disposed in the cathode region 118.

Referring to FIG. 4, in some embodiments, the conductive lines 180m and the via connectors 180v are coupled to the p-type doped structures 140 and 142 in the anode region 114. Further, the conductive lines 180m and the via connectors 180v electrically connect the p-type doped structures 140 and 142 to an anode. In such embodiments, the conductive lines 180m may be referred to as front-side anode conductive lines. The conductive lines 182m and the via connectors 182v are coupled to the n-type doped structures 144 and 146 in the cathode region 118. Further, the conductive lines 182m and the via connectors 182v electrically connect the n-type doped structures 144 and 146 to a cathode. In such embodiments, the conductive lines 182m may be referred to as front-side cathode conductive lines.

Referring to FIG. 5, in some embodiments, the conductive lines 180m and the via connectors 180v electrically connect the p-type doped structures 140 in the VB region 114a of the anode region 114 to the anode, while the p-type doped structure 142 in the VB block region 114b of the anode region 114 is electrically isolated from the anode. In some embodiments, the electrical isolation between the anode and the p-type doped structure 142 may be achieved by an absence of the conductive lines 180m over the p-type dopes structure 142, as shown in FIG. 5. In other embodiments, the electrical isolation between the anode and the p-type doped structure 142 may be achieved by an absence of the conductive lines 180m and the via connector 180v over the p-type doped structure 142. In still other embodiments, the electrical isolation between the anode and the p-type doped structure 142 may be achieved by an absence of the conductive lines 180m, the via connector 180v, and the MD contact 170 over the p-type doped structure 142.

Still referring to FIG. 5, in some embodiments, the conductive lines 182m and the via connectors 182v electrically connect the n-type doped structures 144 in the VB region 118a of the cathode region 118 to a cathode, while the n-type doped structure 146 in the VB block region 118b of the cathode region 118 is electrically isolated from the cathode. In some embodiments, the electrical isolation between the cathode and the n-type doped structure 146 may be achieved by an absence of the conductive lines 182m over the n-type doped structure 146, as shown in FIG. 5. In other embodiments, the electrical isolation between the cathode and the n-type doped structure 146 may be achieved by an absence of the conductive lines 182m and the via connector 182v over the n-type doped structure 146. In still other embodiments, the electrical isolation between the cathode and the n-type doped structure 146 may be achieved by an absence of the conductive lines 182m, the via connector 182v, and the MD contact 172 over the n-type doped structure 146.

In some embodiments, an insulating layer 184 may be disposed over the semiconductor layer 112′ on a back side 112B opposite to the front side 112F. In some embodiments, the insulating layer 184 includes SiN, silicon oxide (SiO), silicon oxynitride (SiON), SiCN, SiOCN, SiCO, or a high-k dielectric material (e.g., HfO, AlO, etc.), but the disclosure is not limited thereto. The insulating layer 184 may serve as a bottom isolation for mitigating a bottom leakage issue.

In some embodiments, a backside BEOL interconnect structure may be disposed over the semiconductor diode structure 110 on the back side 112B of the semiconductor layer 112′. The backside BEOL interconnect structure may be formed through any acceptable process, such as a damascene process, a dual damascene process, or the like. The backside BEOL interconnect structure may further include a backside power distribution network, backside I/O pins and backside power rails (e.g., VDD and VSS). Further, the backside BEOL interconnect structure includes a plurality of backside conductive lines 190m and a plurality of bottom via connectors 190v disposed in the anode region 114. The backside BEOL interconnect structure further includes a plurality of backside conductive lines 192m and a plurality of bottom via connectors 192v disposed in the cathode region 118.

Referring to FIGS. 4 and 5, the bottom via connectors 190v and 192v penetrate the insulating layer 184 and the semiconductor layer 112′ from the back side 112B. Further, the bottom via connectors 190v are coupled to the p-type doped structures 140 in the VB region 114a of the anode region 114, and the bottom via connectors 192v are coupled to the n-type doped structures 144 in the VB region 118a of the cathode region 118. It is worth noting that the p-type doped structure 142 in the VB blocking region 114b of the anode region 114 is isolated from the bottom via connectors 190v, and the n-type doped structure 146 in the VB blocking region 118b of the cathode region 118 is isolated from the bottom via connectors 192v. The backside conductive line 190m is electrically connected to the p-type doped structure 140 in the anode region 114 through the bottom via connectors 190v, and the backside conductive line 192m is electrically connected to the n-type doped structure 144 in the cathode region 118 through the bottom via connectors 192v. In some embodiments, the backside conductive line 190m is electrically connected to a backside anode and is therefore being referred to as a backside anode conductive line. The backside conductive line 192m is electrically connected to a backside cathode and is therefore referred to as a backside cathode conductive line. In such embodiments, the p-type doped structure 142 in the VB blocking region 114b is electrically isolated from the backside anode, and the n-type doped structure 146 in the VB blocking region 118b is electrically isolated from the backside cathode.

Still referring to FIGS. 4 and 5, during an ESD stress or an ESD event, the semiconductor diode structure 110 is biased, and an ESD current i flows through the semiconductor diode structure 110 from the anode to the cathode. In some embodiments, the ESD current i may flow from the front-side anode conductive lines 180m, the front-side via connector 180v and the MD contacts 170, then into the p-type doped structures 140 in the VB region 114a of the anode region 114. In some embodiments, the ESD current i may also flow from the front-side anode conductive lines 180m, the front-side via connector 180v and the MD contacts 170, then into the p-type doped structure 142 in the VB blocking region 114b of the anode region 114, as shown in FIG. 4. The ESD current i may flow from the backside anode conductive lines 190m and the bottom via connector 190v, then into the p-type doped structures 140 in the VB region 114a of the anode region 114.

In some embodiments, the ESD current i flows from the p-type doped structures 140 in the VB region 114a into the p-type doped structure 142 in the VB blocking region 114b through the nanostructure channels 122 wrapped by the metal gates 154a and the nanostructure channels 122 wrapped by the metal gate 154b. The ESD current i is forced to flow from the p-type doped structure 142 into the semiconductor layer 112′, as shown in FIGS. 4 and 5. In such embodiments, the p-type doped structure 142 that directs the ESD current i into the semiconductor layer 112′ may be referred to as a conduction structure or a tap structure.

In the intervening region 116, the ESD current i flows from the anode region 114 to the cathode region 118 through the semiconductor layer 112′ under the central structure 160.

In some embodiments, the ESD current i then flows from the semiconductor layer 112′ into the n-type doped structure 146 in the VB blocking region 118b of the cathode region 118. In some embodiments, the ESD current i is then forced to flow from the n-type doped structure 146 in the VB blocking region 118b to the n-type doped structure 144 in the VB region 118a through the nanostructure channels 122. In such embodiments, the n-type doped structure 146 that directs the ESD current i from the semiconductor layer 112′ may be referred to as a conduction structure or a tap structure.

In some embodiments, the ESD current i flows to the n-type doped structure 144 in the VB region 118a from the n-type doped structure 146 in the VB blocking region 118b through the nanostructure channels 122 wrapped by the metal gates 158b and the nanostructure channels 122 wrapped by the metal gate 158a. The ESD current i then flows into the front-side cathode conductive lines 182m and the backside cathode conductive lines 192m through the n-type doped structures 144 in the VB region 118a, as shown in FIG. 4. In some embodiments, the ESD current i flows from the n-type doped structure 144 into the front-side cathode conductive lines 182m though the MD contacts 172 and the front-side via connectors 182v, and into the backside cathode conductive lines 192m through the bottom via connectors 192v. Accordingly, the internal circuit 102 (shown in FIG. 1) is protected from the current i from the ESD event by the semiconductor diode structure 110 (i.e., 110a and 110b).

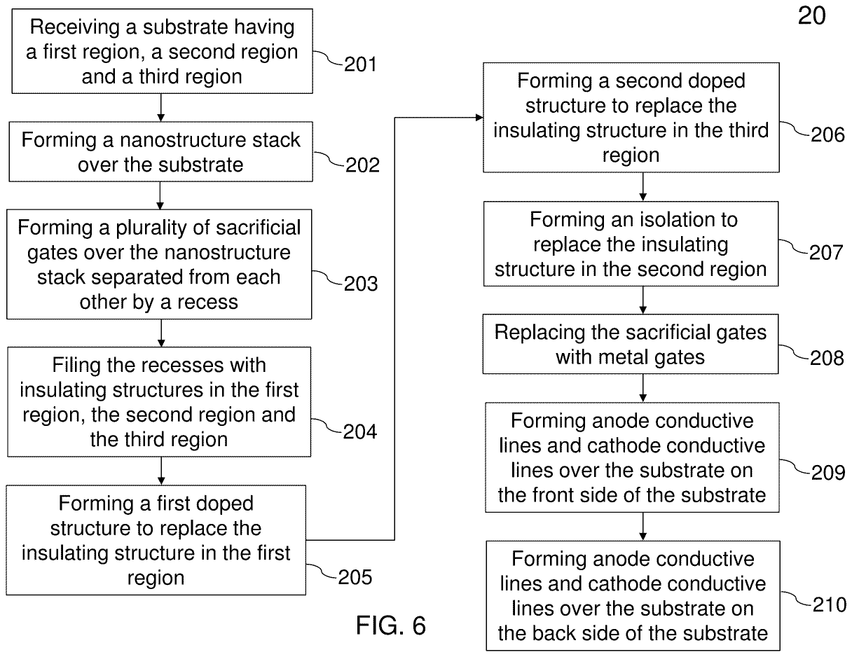

FIG. 6 is a flowchart representing a method for forming a semiconductor diode structure 20 according to aspects of the present disclosure. The method 20 includes a number of operations (201, 202, 203, 204, 205, 206, 207, 208, 209 and 210). The method 20 will be further described according to one or more embodiments. It should be noted that the operations of the method 20 may be rearranged or otherwise modified within the scope of the various aspects. It should be further noted that additional processes may be provided before, during, and after the method 20, and that some other processes may be briefly described herein. Thus, other implementations are possible within the scope of the various aspects described herein.

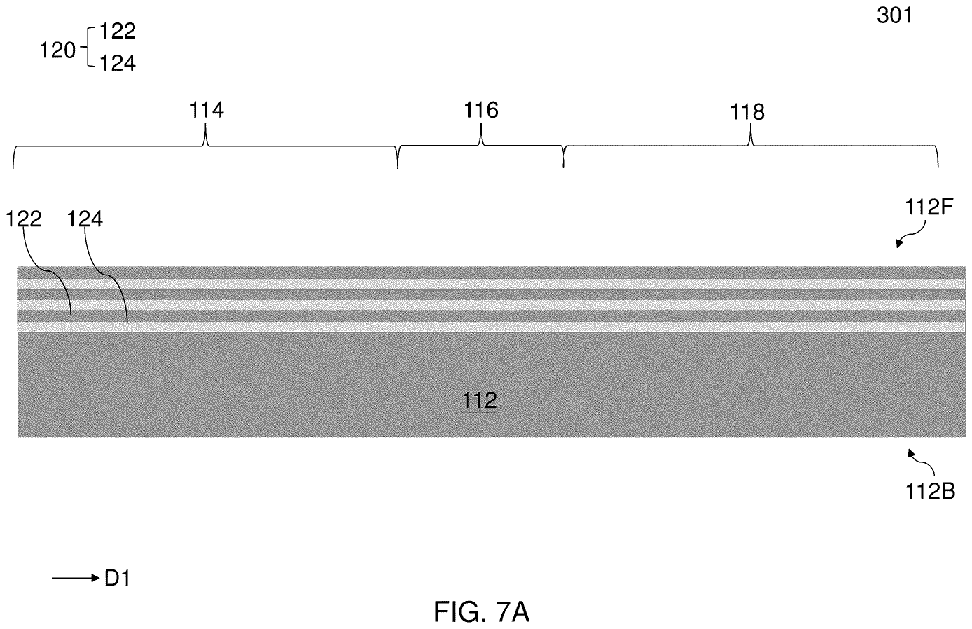

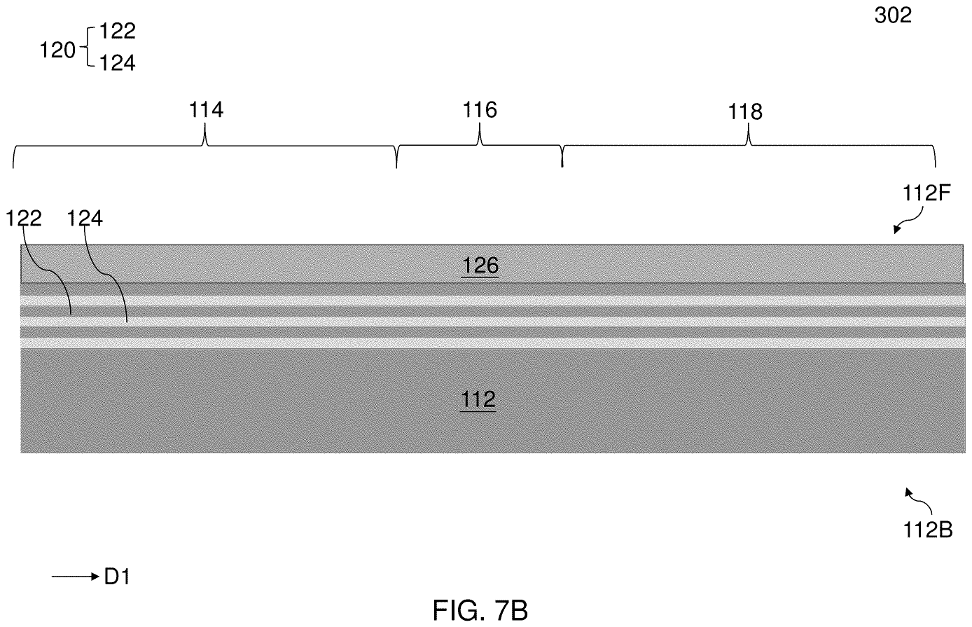

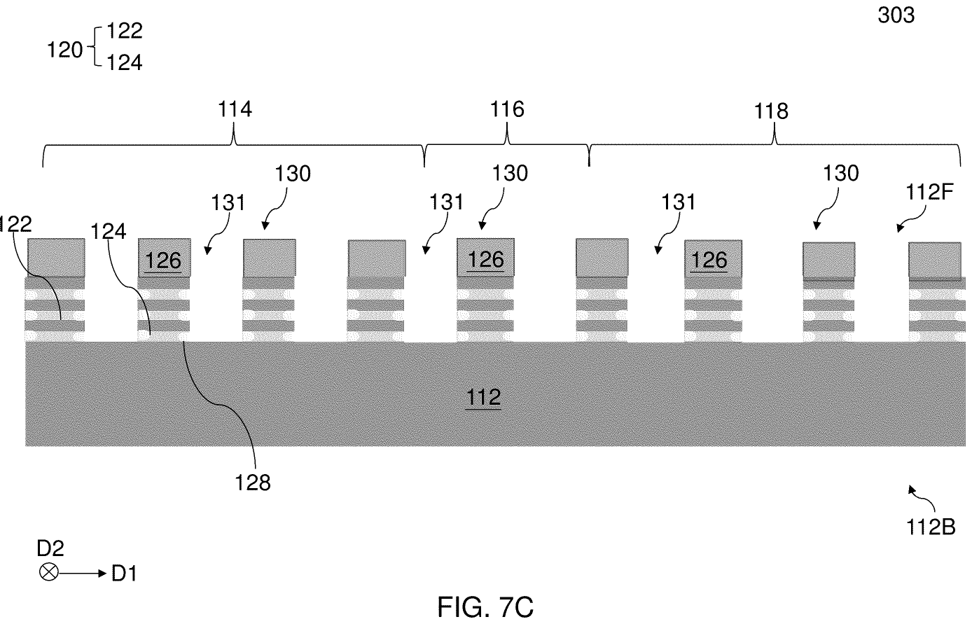

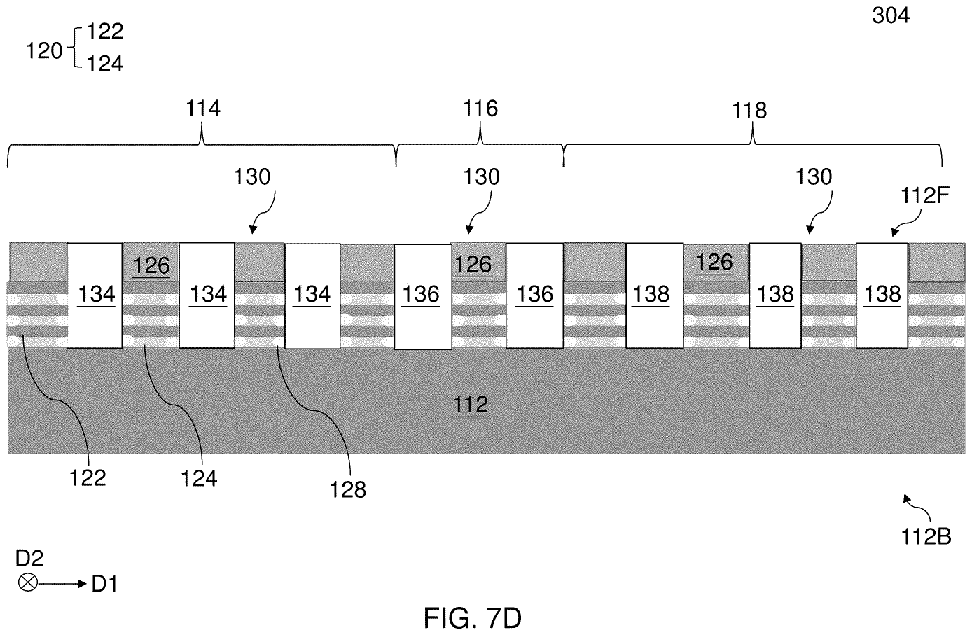

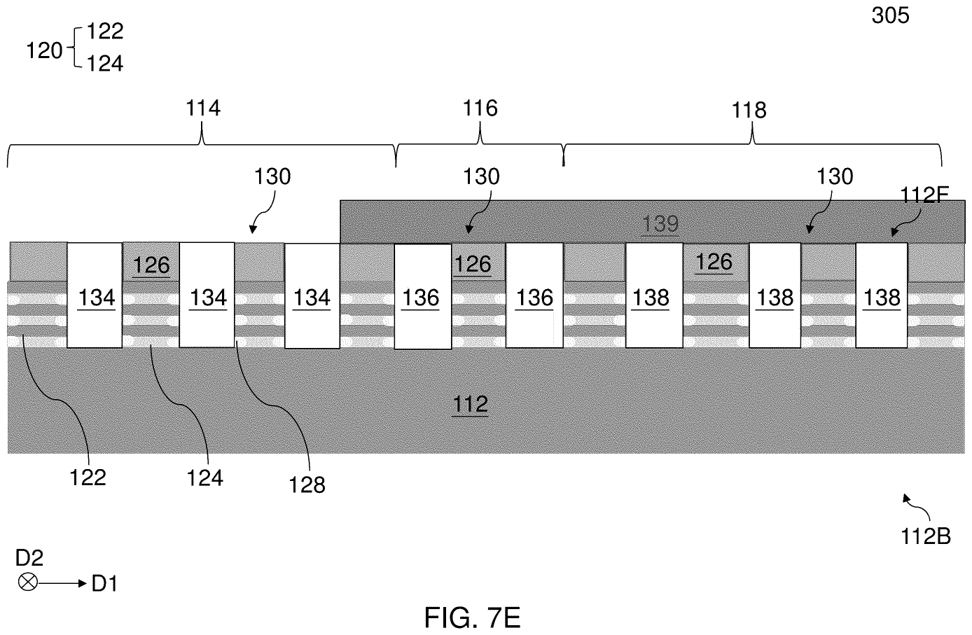

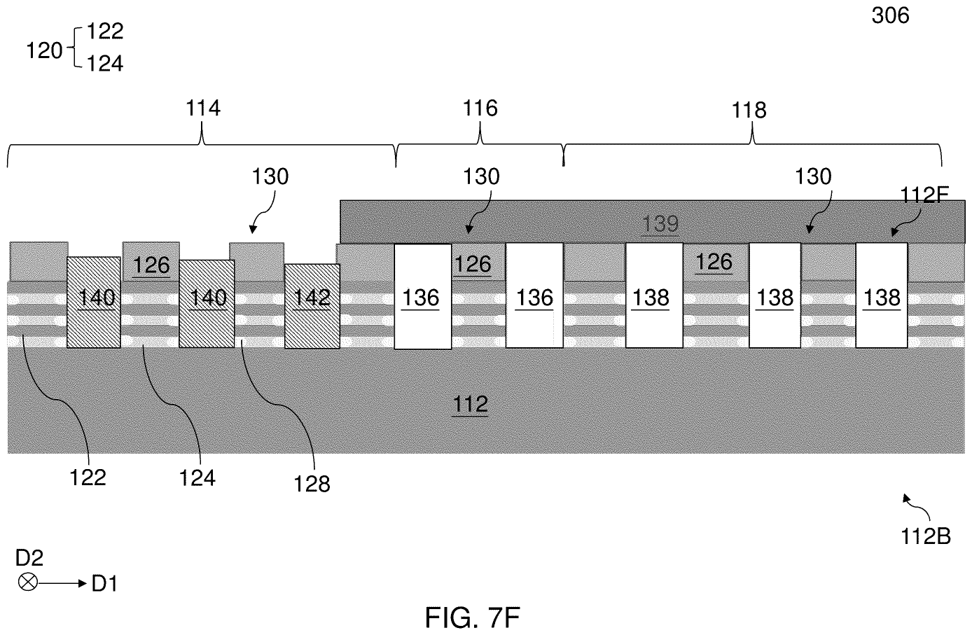

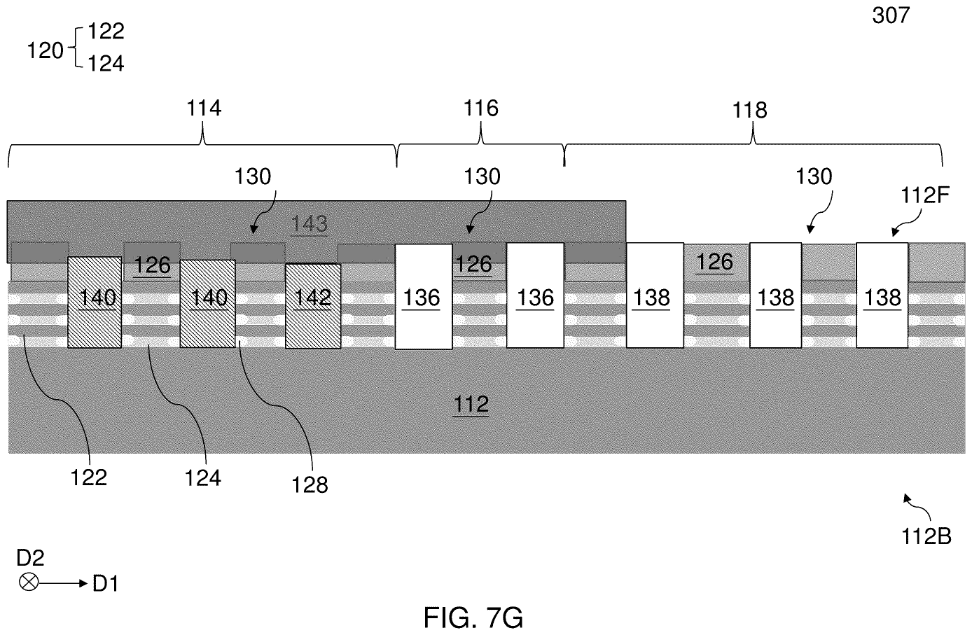

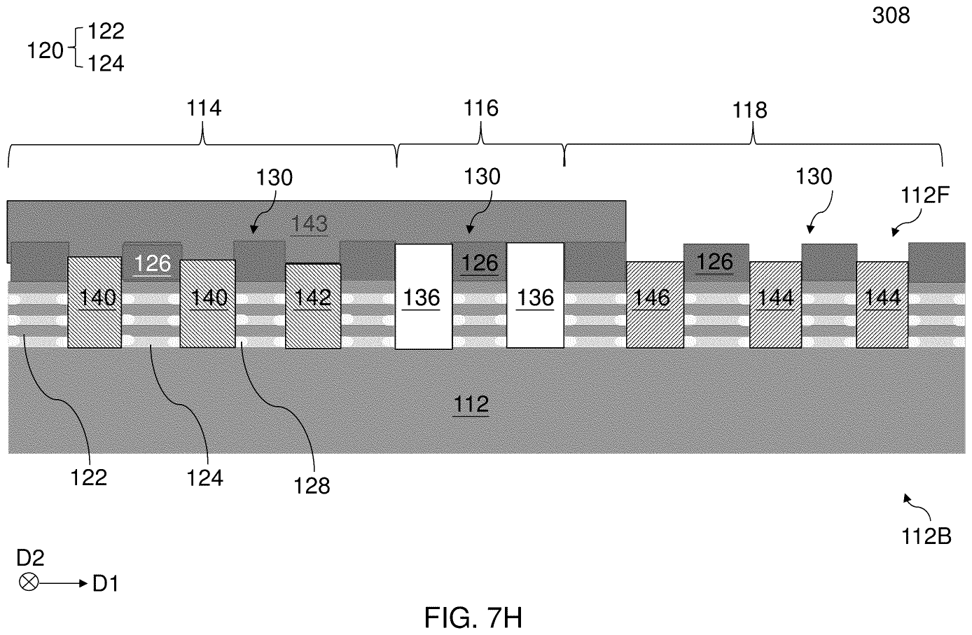

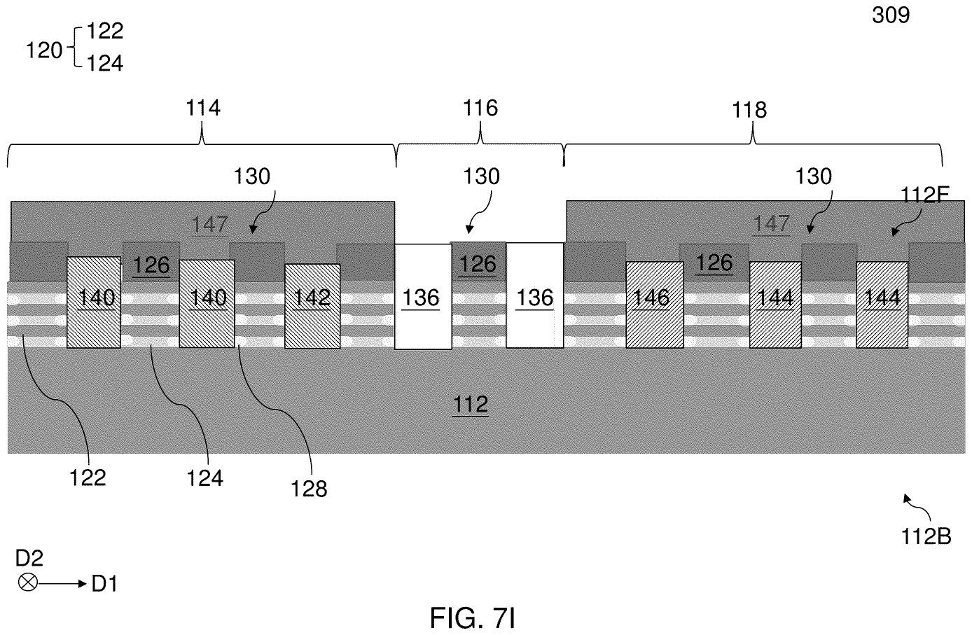

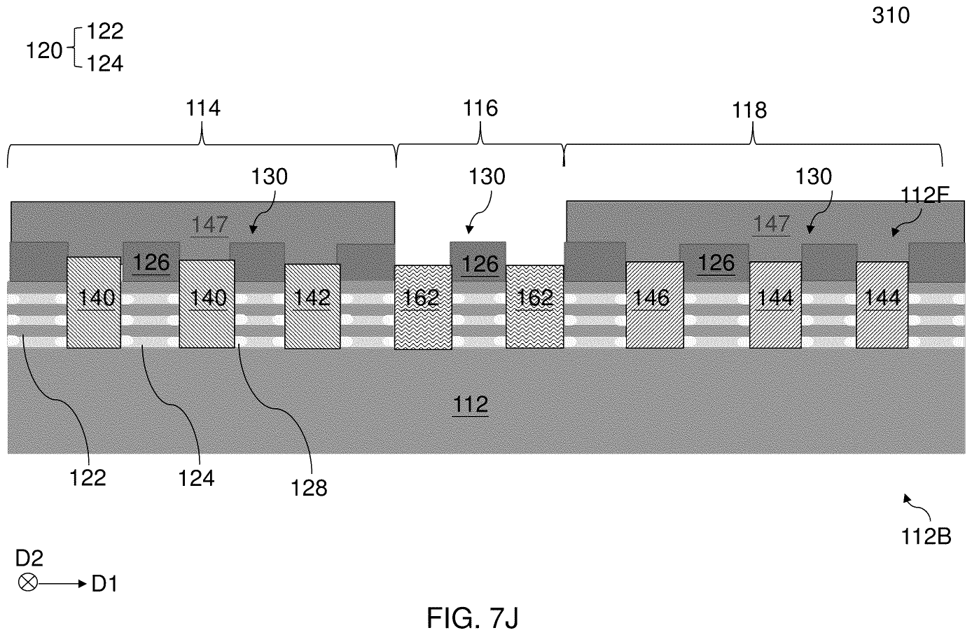

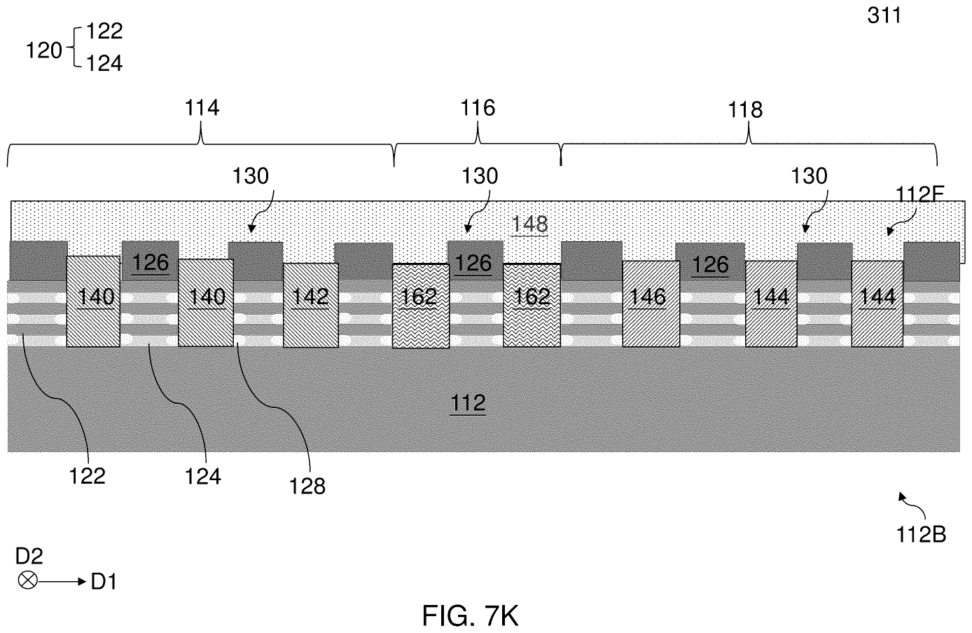

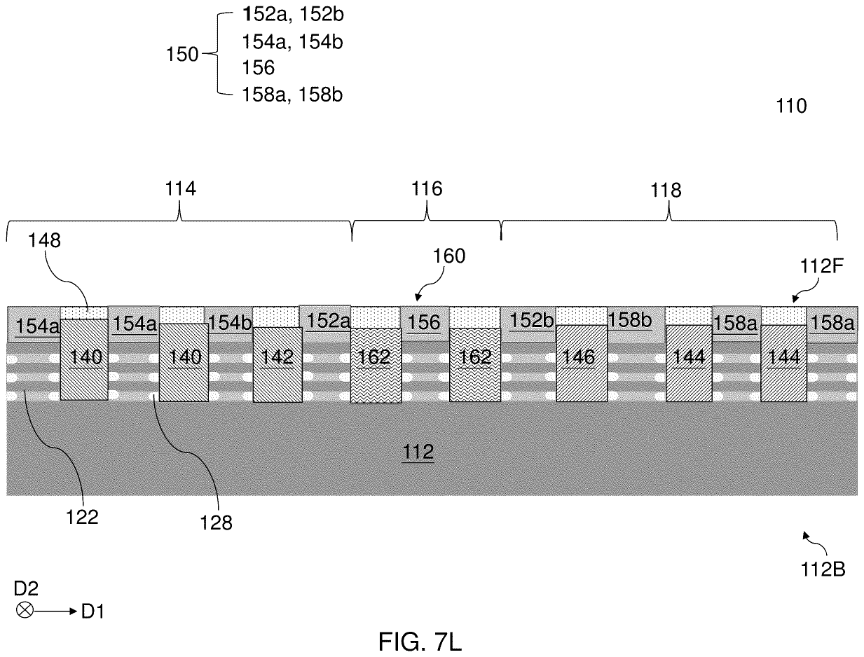

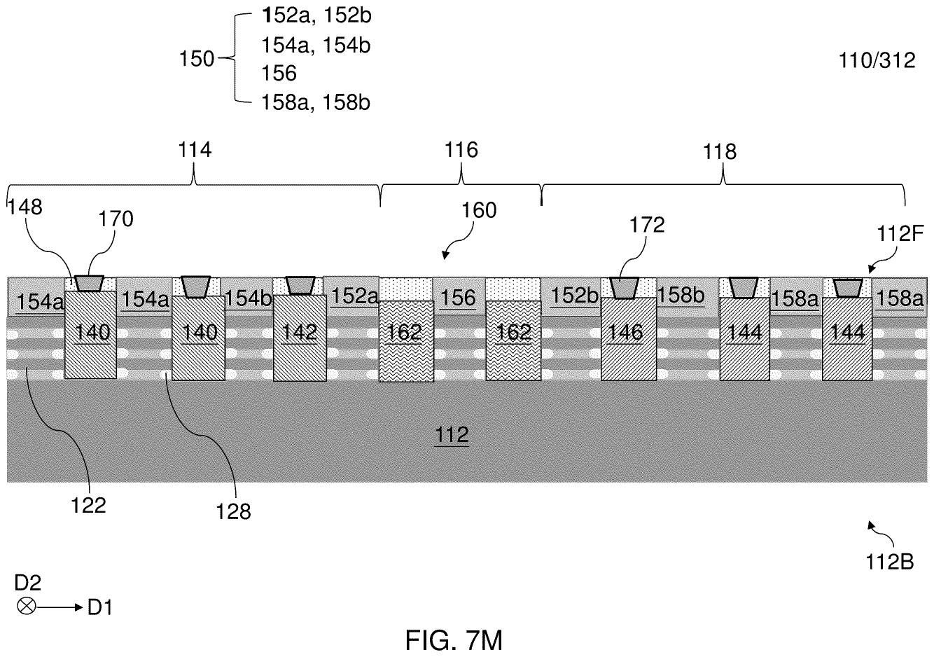

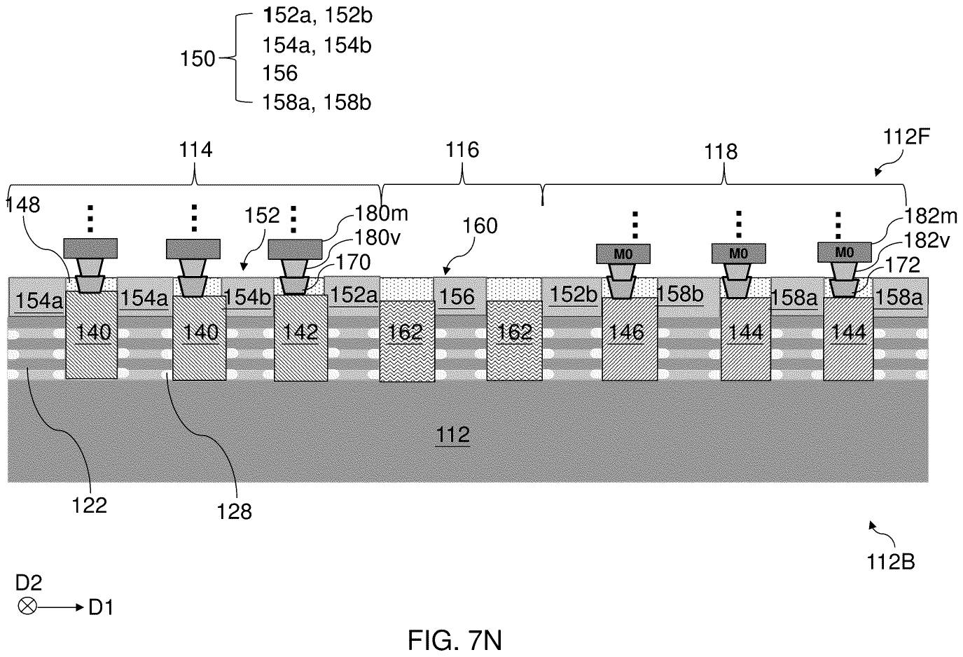

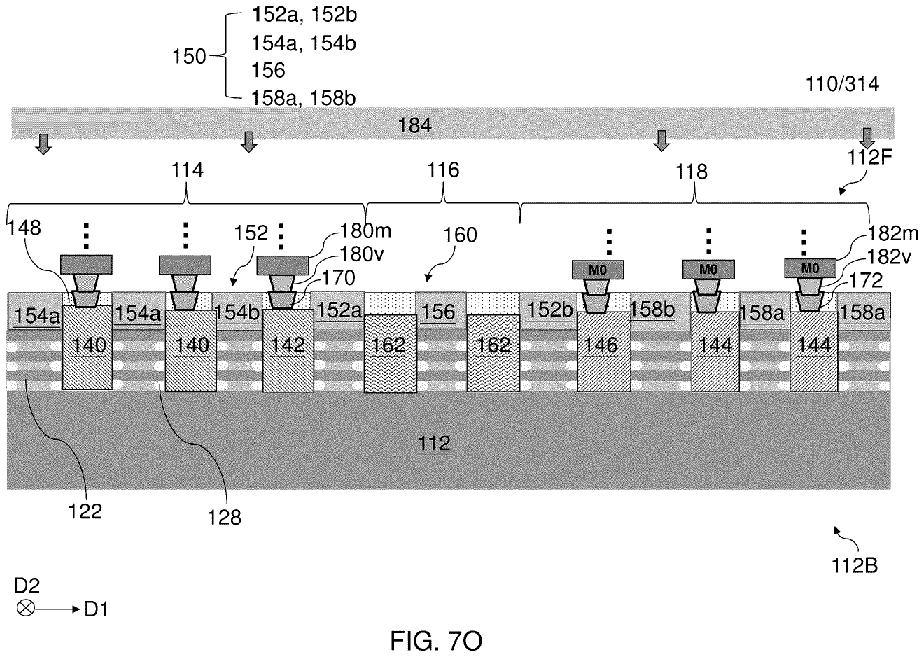

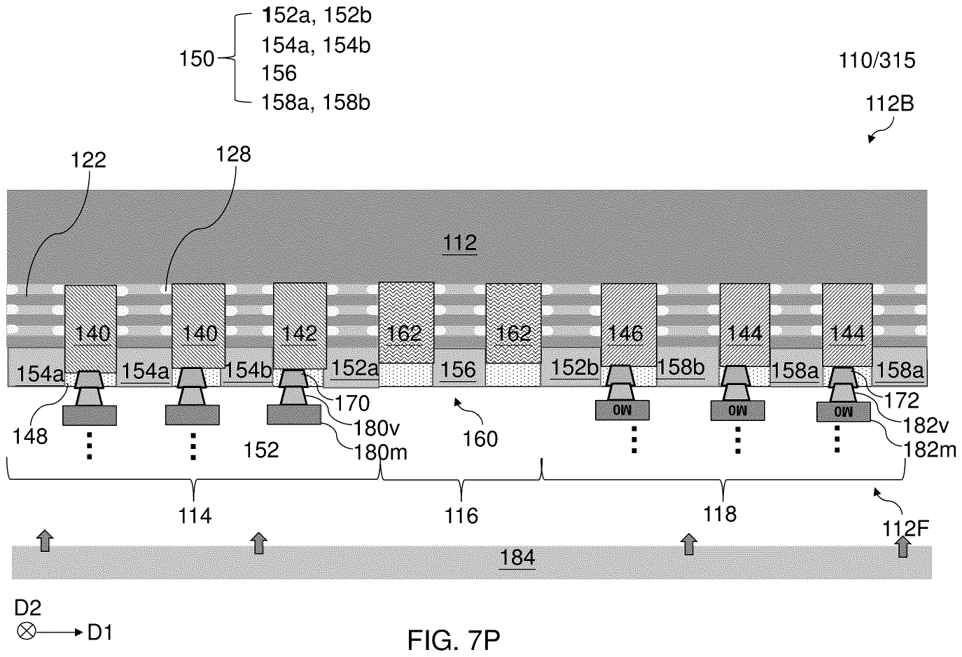

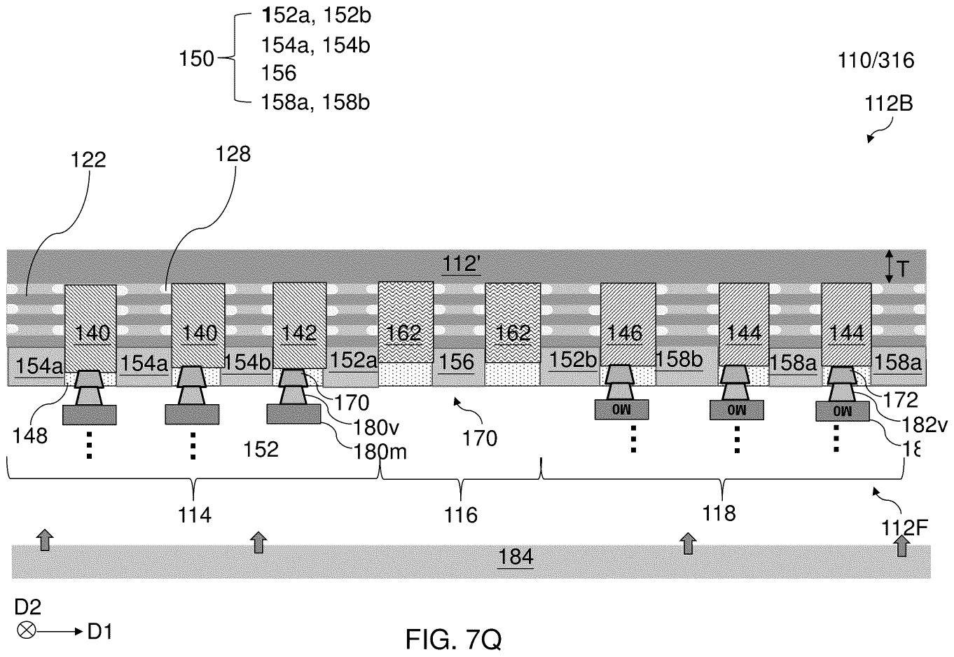

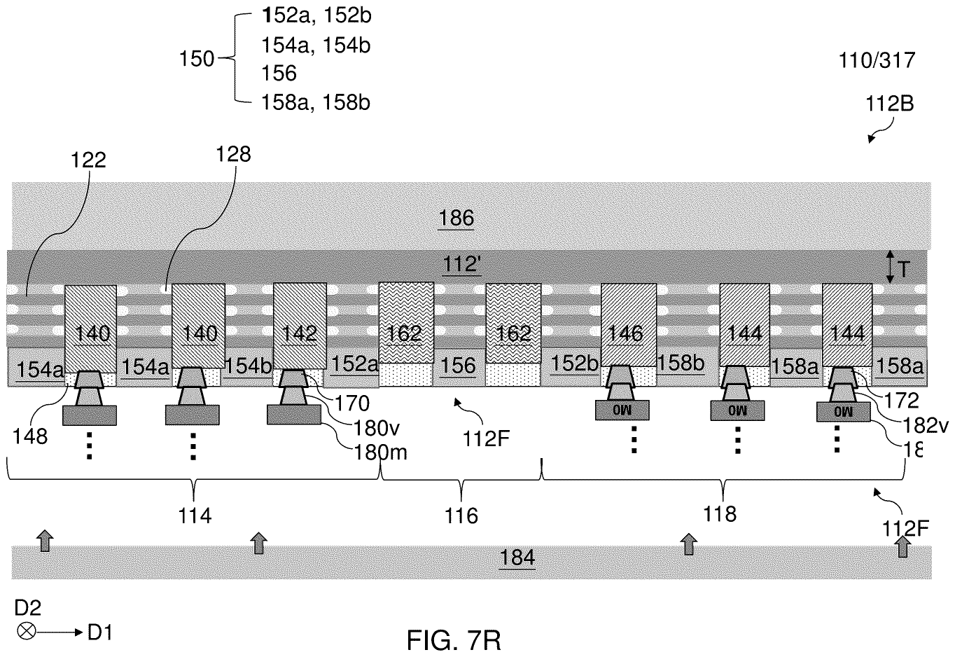

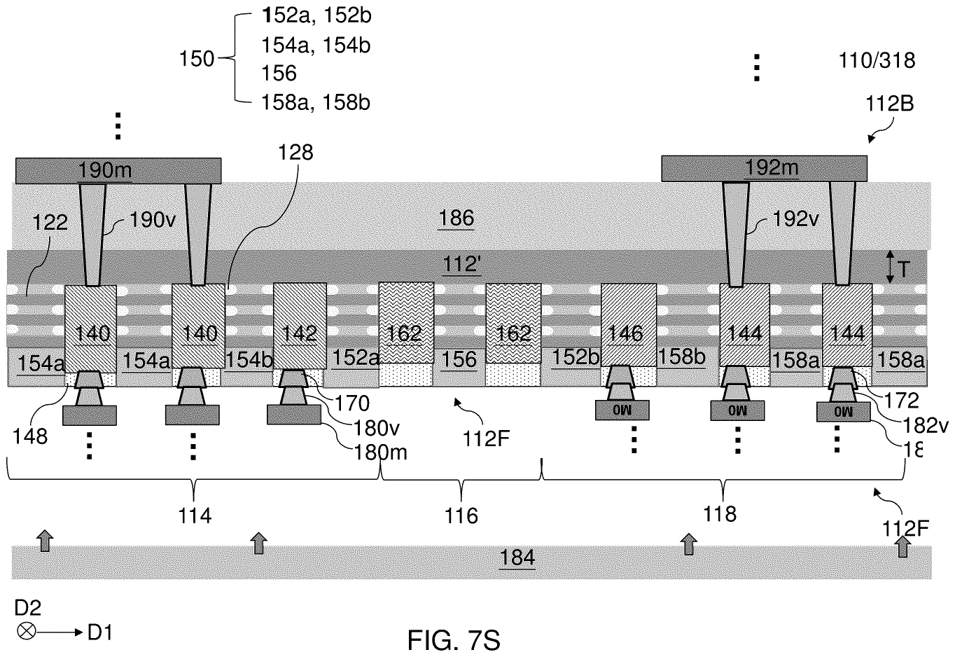

FIGS. 7A to 7S are schematic cross-sectional views of a semiconductor diode structure at various fabrication stages constructed according to aspects of one or more embodiments of the present disclosure. For example, FIG. 7A is a schematic cross-sectional view of an intermediate semiconductor structure 301 according to some embodiments corresponding to operation 201. In operation 201, a substrate 112 is received. The substrate 112 may be a semiconductor substrate, such as a bulk semiconductor, a semiconductor-on-insulator (SOI) substrate, or the like, and may be doped (e.g., with a p-type or an n-type dopant) or undoped. The substrate 112 may be a wafer, such as a silicon wafer. Other substrates, such as a multi-layered or gradient substrate, may also be used. In some embodiments, a semiconductor material of the substrate 112 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or a combination thereof. In some embodiments, isolation structures such as shallow trench isolation (STI) structures may be formed in the substrate 112 in order to define a region where the semiconductor diode structure 110 is to be formed, although such isolation structures are not shown in FIGS. 7A to 7S. In some embodiments, a first region 114, a second region 116 and a third region 118 may be defined over the substrate 112. In some embodiments, the first region 114 may be defined as an anode region, the third region 118 may be defined as a cathode region, and the second region 116 may be defined as an intervening region. In such embodiments, the second region 116 may be defined between the first region 114 and the third region 118. Further, the first region 114 is adjacent to the second region 116, and the second region 116 is adjacent to the third region 118, as shown in FIG. 7A.

Still referring to FIG. 7A, in some embodiments, a plurality of alternating semiconductor layers 122 and 124 are formed over the substrate 112 on a front side 112F. The alternating semiconductor layers 122 and 124 may be used to selectively process some of the layers. Accordingly, compositions of the semiconductor layers 122 and 124 may have different oxidation rates, etchant sensitivity, and/or other differing properties. The semiconductor layers 122 and 124 may have thicknesses chosen based on device performance considerations. In some embodiments, the semiconductor layers 122 are substantially uniform in thickness, and the semiconductor layers 124 are substantially uniform in thickness. In some embodiments, either of the semiconductor layers 122 and 124 may include Si. In some embodiments, either of the semiconductor layers 122 and 124 may include other materials such as Ge, a compound semiconductor such as silicon carbide (SiC), gallium arsenide (GaAs), gallium phosphide (GaP), indium phosphide (InP), indium arsenide (InAs), and/or indium antimonide (InSb), an alloy semiconductor such as SiGe, GaAsP, AlInAs, AlGaAs, InGaAs, GaInP, and/or GaInAsP, or combinations thereof. In some embodiments, the semiconductor layers 122 and 124 may be undoped or substantially dopant-free, where, for example, no doping is performed during an epitaxial growth process. Alternatively, the semiconductor layers 122 and 124 may be doped. For example, the semiconductor layers 122 or 124 may be doped with a p-type dopant such as boron (B), aluminum (Al), In, or Ga for forming a p-type channel, or an n-type dopant such as P, As, or Sb for forming an n-type channel. In some embodiments, each of the semiconductor layers 122 (e.g., Si layers) and the semiconductor layers 124 (e.g., SiGe layers), is epitaxially grown on its underlying layer. In some embodiments, the epitaxial growth can use chemical vapor deposition (CVD), metal-organic CVD (MOCVD), molecular beam epitaxy (MBE), liquid phase epitaxy (LPE), vapor phase epitaxy (VPE), ultra-high vacuum CVD (UHVCVD), or a combination thereof.

Please refer to FIG. 7B, which is a schematic cross-sectional view of an intermediate semiconductor structure 302 according to some embodiments corresponding to operation 202. In some embodiments, in operation 202, a nanostructure stack 120 is formed over the substrate 112 on the front side 112F. In some embodiments, the semiconductor layers 122 and 124 are patterned to form at least a nanostructure stack 120. In some embodiments, the nanostructure stack 120 may include a fin-like structure over the substrate 112. In such embodiments, the fin-like structure may extend in a direction D1. Suitable photolithography and etch operations may be performed on the semiconductor layers 122 and 124, thereby forming the nanostructure stack 120 (i.e., the fin-like structure). In some embodiments, the forming of the nanostructure stack 120 may further include a trim process to decrease a width and/or a height of the nanostructure stack 120. The trim process may include wet or dry etching processes. A height and a width of the nanostructure stack 120 may be chosen based on device performance considerations.

In some embodiments, a liner may be conformally formed over the nanostructure stack 120. Accordingly, tops and sidewalls of the nanostructure stack 120 may be covered by the liner. In some embodiments, the liner includes dielectric materials such as SIN, SiON, silicon carbonitride (SiCN), silicon oxycarbonitride (SiOCN), or other appropriate material. In some embodiments, a semiconductor layer 126 is formed over the nanostructure stack 120, as shown in FIG. 7B. The semiconductor layer 126 may include amorphous silicon, polycrystalline-silicon (polysilicon), or poly-crystalline silicon-germanium (poly-SiGe). The semiconductor layer 126 may be deposited by physical vapor deposition (PVD), CVD, sputter deposition, or other techniques for depositing the selected material.

Please refer to FIG. 7C, which is a schematic cross-sectional view of an intermediate semiconductor structure 303 according to some embodiments corresponding to operation 203. In some embodiments, in operation 203, a plurality of sacrificial gates 130 are formed over the substrate 112 on the front side 112F. In some embodiments, suitable photolithography and etching operations may be performed to pattern the semiconductor layer 126 and the nanostructure stack 120. In some embodiments, the etching operation may be any acceptable etch process, such as a reactive ion etch (RE), a neutral beam etch (NBE), the like, or a combination thereof. The etching may be anisotropic. Accordingly, portions of the semiconductor layer 126, portions of the semiconductor layers 124 and portions of the semiconductor layer 122 are removed, thereby forming the sacrificial gates 130. As shown in FIG. 7C, recesses 131 are formed in the first region 114, the second region 116 and the third region 118. The sacrificial gates 130 may be replaced at a later processing stage by a metal gate electrode (MG) as discussed below. As shown in FIG. 7C, each of the sacrificial gates 130 extends along the direction D2, which is different from the direction D1. Additionally, the sacrificial gates 130 may be arranged in the direction D1. Each of the sacrificial gates 130 covers a portion of the nanostructure stack 120, as shown in FIG. 7C. Further, the sacrificial gates 130 are separated from each other by a recess 131, wherein the nanostructure stack 120 is interrupted by the recesses 131. Additionally, sidewalls of the semiconductor layers 122 and sidewalls of the semiconductor layers 124 are therefore exposed through the recesses 131.

In some embodiments, the exposed semiconductor layers 124 of the nanostructure stack 120 are partially removed, and thus a plurality of notches (not shown) are formed between the remaining semiconductor layers 122. In some embodiments, an insulating layer is formed to fill the notches. Subsequently, portions of the insulating layer may be removed, thereby forming inner spacers 128, as shown in FIG. 7C.

Please refer to FIG. 7D, which is a schematic cross-sectional view of an intermediate semiconductor structure 304 according to some embodiments corresponding to operation 204. In some embodiments, in operation 204, the recesses 131 are filled with insulating structures 134, 136 and 138. In some embodiments, the insulating structures 134 are formed in the first region 114, the insulating structures 136 are formed in the second region 116, and the insulating structures 138 are formed in the third region 118. In some embodiments, the insulating structures 134, 136 and 138 may include insulating materials such as aluminum oxide (AlOx), but the disclosure is not limited thereto. In some embodiments, the insulating structures 134, 136 and 138 may be formed by filling the recesses 131 with the insulating material and a planarization is then performed, such as a chemical mechanical polish (CMP), but the disclosure is not limited thereto. In such embodiments, top surfaces of the insulating structures 134, 136 and 138 are aligned (i.e., coplanar or flush) with top surfaces of the sacrificial gates 130.

Please refer to FIGS. 7E and 7F, which are schematic cross-sectional views of intermediate semiconductor structures 305 and 306 according to some embodiments corresponding to operation 205. In operation 205, the insulating structures 134 in the first region 114 are replaced with doped structures 140 and 142. In some embodiments, operation 205 includes further operations. For example, referring to FIG. 7E, a patterned mask layer 139 may be formed over the substrate 112 on the front side 112F. In some embodiments, the patterned mask layer 139 may be a patterned photoresist, but the disclosure is not limited thereto. In some embodiments, the patterned mask layer 139 covers the sacrificial gates 130, the nanostructure stack 120 and the insulating structures 136 and 138 in the second region 116 and the third region 118.

Referring to FIG. 7F, in some embodiments, a suitable etching operation is performed to remove the insulating structures 134 in the first region 114, thereby forming openings (not shown) over the substrate 112 on the front side 112F. Subsequently, the doped structures 140 and 142 are formed to fill the openings. In some embodiments, each of the doped structures 140 and 142 includes an epitaxial doped structure. Further, the epitaxial doped structures 140 and 142 can be taller than the nanostructure stack 120. In some embodiments, the epitaxial doped structures 140 and 142 are formed by growing a strained material in the recesses by an epitaxial (epi) process. In such embodiments, a lattice constant of the strained material may be different from a lattice constant of the substrate 112. Further, the strained material formed by the epi process may be doped either through an implanting process to implant appropriate dopants, or by in-situ doping as the material is grown. In some embodiments, each of the doped structures 140 and 142 includes an epitaxial p-type doped structure formed of SiGe or Ge doped with boron (B) to form a p-type region.

Please refer to FIGS. 7G and 7H, which are schematic cross-sectional views of intermediate semiconductor structures 307 and 308 according to some embodiments corresponding to operation 206. In operation 206, the insulating structures 138 in the third region 118 are replaced with doped structures 144 and 146. In some embodiments, operation 206 includes further operations. For example, referring to FIG. 7G, a patterned mask layer 143 may be formed over the substrate 112 on the front side 112F. In some embodiments, the patterned mask layer 143 may be a patterned photoresist, but the disclosure is not limited thereto. In some embodiments, the patterned mask layer 143 covers the sacrificial gates 130 and the nanostructure stack 120 in the first region 114 and the second region 116, covers the insulating structures 136 in the second region 116, and covers the doped structures 140 and 142 in the first region 114.

Referring to FIG. 7H, in some embodiments, a suitable etching operation is performed to remove the insulating structures 138 in the third region 118, thereby forming openings (not shown) over the substrate 112 on the front side 112F. Subsequently, the doped structures 144 and 146 are formed to fill the openings. In some embodiments, each of the doped structures 144 and 146 includes an epitaxial doped structure. Further, the epitaxial doped structures 144 and 146 can be taller than the nanostructure stack 120. In some embodiments, the epitaxial doped structures 144 and 146 are formed by growing a strained material in the recesses by an epitaxial (epi) process. In such embodiments, a lattice constant of the strained material may be different from a lattice constant of the substrate 112. Further, the strained material formed by the epi process may be doped either through an implanting process to implant appropriate dopants, or by in-situ doping as the material is grown. In some embodiments, each of the doped structures 144 and 146 includes an epitaxial n-type doped structure formed of SiC or SiP doped with phosphorus (P). Accordingly, dopants in the doped structures 140, 142 and dopants in the doped structures 144, 146 are complementary.

Please refer to FIGS. 7I and 7J, which are schematic cross-sectional views of intermediate semiconductor structures 309 and 310 according to some embodiments corresponding to operation 207. In operation 207, the insulating structures 136 in the second region 116 are replaced with isolations 162. In some embodiments, operation 207 includes further operations. For example, referring to FIG. 7I, a patterned mask layer 147 may be formed over the substrate 112 on the front side 112F. In some embodiments, the patterned mask layer 147 may be a patterned photoresist, but the disclosure is not limited thereto. In some embodiments, the patterned mask layer 147 covers the sacrificial gates 130, the nanostructure stack 120 and the doped structures 140 and 142 in the first region 114. The patterned mask layer 147 also covers the sacrificial gates 130, the nanostructure stack 120 and the doped structures 144 and 146 in the third region 118.

Referring to FIG. 7J, in some embodiments, a suitable etching operation is performed to remove the insulating structures 136 in the second region 116, thereby forming openings (not shown) over the substrate 112 on the front side 112F. Subsequently, isolations 162 are formed to fill the openings. In some embodiments, each of the isolations 162 includes an insulating material such as, for example but not limited thereto, silicon nitride. In some embodiments, the isolations 162 may be formed by suitable depositions. In some embodiments, top surfaces of the isolations 162 may be lower than the top surfaces of the sacrificial gates 130. In other embodiments, the top surfaces of the isolations 162 may be aligned with (i.e., coplanar or flush with) the top surfaces of the sacrificial gates 130.

In some embodiments, because the second region 116 is free of the epi-grown doped structures 140, 142, 144 and 146, the second region 116 may be referred to as an epi-blocking region. Additionally, by modifying the patterned mask layer 147, an area of the epi-blocking region can be increased such that a quantity of the isolations 162 can be increased, as shown in FIG. 3.

Please refer to FIG. 7K, which is a schematic cross-sectional view of an intermediate semiconductor structure 311 according to some embodiments corresponding to operation 208. In operation 208, the sacrificial gates 130 are replaced with metal gates 150. In some embodiments, operation 208 includes further operations. For example, as shown in FIG. 7K, after the forming of the isolations 162, a dielectric structure 148 may be formed over the substrate 112 on the front side 112F. In some embodiments, the dielectric structure 148 may include at least a contact etch-stop layer (CESL) and an interlayer dielectric (ILD) over the CESL. In some embodiments, the CESL can include silicon nitride, silicon oxynitride, and/or other applicable materials. In some embodiments, the ILD may include multilayers made of multiple dielectric materials, such as silicon oxide, silicon nitride, silicon oxynitride, tetraethoxysilane (TEOS), phosphosilicate glass (PSG), borophosphosilicate glass (BPSG), low-k dielectric material, and/or other applicable dielectric materials. Examples of low-k dielectric materials include, but are not limited to, fluorinated silica glass (FSG), carbon doped silicon oxide, amorphous fluorinated carbon, parylene, bis-benzocyclobutenes (BCB), and polyimide.

Please refer to FIG. 7L, which is a schematic cross-sectional view of a semiconductor structure 110 according to some embodiments corresponding to operation 208. Referring to FIG. 7L, in some embodiments, a polishing process such as a CMP process is performed on the ILD and the CESL to expose top surfaces of the semiconductor layer 126 of the sacrificial gates 130. Subsequently, the semiconductor layer 126 of the sacrificial gates 130 is removed to form a plurality of trenches (not shown). Next, portions of the nanostructure stack 120 are removed. In some embodiments, a selective removal process for the semiconductor layers 124 (e.g., SiGe layers) is performed. In some embodiments, the selective removal process may include use of an etchant that selectively etches the silicon germanium at a higher rate than the silicon, such as NH₄OH:H₂O₂:H₂O (ammonia peroxide mixture, APM), H₂SO₄+H₂O₂ (sulfuric acid peroxide mixture, SPM), or the like. Other suitable processes and materials may be used. This selective etching process removes the semiconductor layers 124, leaving the semiconductor layers 122 in place and separate from each other in the trenches. The remaining semiconductor layers 122 may serve as nanostructure channels 122. Additionally, in some embodiments, each of the nanostructure channels 122 may be trimmed to have a desired shape and desired dimensions (i.e., thickness and width). By adjusting the width and the thickness of the nanostructure channels 122, a threshold voltage (Vt) of a FET device to be formed can be adjusted to meet design specifications.

Still referring to FIG. 7L, in some embodiments, an interfacial layer (IL) (not shown) may be formed over each of the nanostructure channels 122. Subsequently, a high-k gate dielectric layer (not shown) is formed over the IL to surround each of the nanostructure channels 122. In some embodiments, the high-k gate dielectric layer includes a high-k dielectric material having a high dielectric constant, for example, a dielectric constant greater than that of thermal silicon oxide (˜3.9). The high-k dielectric material may include hafnium oxide (HfO₂), zirconium oxide (ZrO₂), lanthanum oxide (La₂O₃), aluminum oxide (Al₂O₃), titanium oxide (TiO₂), yttrium oxide (Y₂O₃), strontium titanate (SrTiO₃), hafnium oxynitride (HfOₓN), other suitable metal-oxides, or combinations thereof.

In some embodiments, work function metal layers and gap-filling metal layers may be formed over the substrate 112. The work function metal layer is formed to surround each of the nanostructure channels 122. Further, the work function metal layer is formed on the high-k gate dielectric layer. In some embodiments, by selecting a metal material and adjusting a thickness of the work function metal layers, the Vt of the FET device can be adjusted. In some embodiments, the work function metal layer is conformally formed over the nanostructure channels 122. Accordingly, the IL, the high-k gate dielectric layer, the work function metal layer and the gap-filling metal layer form a continuous structure that surrounds all the nanostructure channels and is referred to as the metal gates 150. In some embodiments, the metal gates 150 include at least a metal gate 152a, at least a metal gate 152b, metal gates 154a and 154b, at least a metal gate 156, and metal gates 156a and 156b.

In some embodiments, a semiconductor diode structure 110 is obtained, as shown in FIG. 7L. The semiconductor diode structure 110 includes the doped structures (i.e., the p-type doped structures 140 and 142) disposed in the first region 114, the doped structures (i.e., the n-type doped structures 144 and 146) disposed in the third region 118, and the isolations 162 disposed in the second region 116. In some embodiments, the metal gates 154a are disposed between adjacent pair of the doped structures 140 in the first region 114, and the metal gate 154b is disposed between the doped structure 140 and the doped structure 142 in the first region 114. The metal gate 152a is disposed between the doped structure 142 in the first region 114 and the isolation 162 in the second region 116, and the metal gate 152b is disposed between the isolation 162 in the second region 116 and the doped structure 146 in the third region 118. The metal gate 156 is disposed between adjacent isolations 162 in the second region 116. In some embodiments, the metal gate 156 and the isolations 162 in the second region 116 can be referred to as a central structure 160. In some embodiments, the metal gates 158a are disposed between adjacent pairs of the doped structures 144 in the third region 118, and the metal gate 158b is disposed between the doped structure 144 and the doped structure 146 in the third region 118. In such embodiments, structures (i.e., the nanostructure channels 122, the metal gates 154a, 154b, and the doped structures 140, 142) in the first region 114 and structures (i.e., the nanostructure channels 122, the metal gates 158a, 158b, and the doped structures 144, 146) in the third region 118 are line symmetric about the central structure 160.

Please refer to FIGS. 7M and 7N, which are schematic cross-sectional views of intermediate semiconductor structures 312 and 313 according to some embodiments corresponding to operation 209. In operation 209, anode conductive lines and cathode conductive lines are formed over the substrate 112 on the front side 112F. In some embodiments, operation 209 includes further operations. For example, dielectric structures (not shown) may be formed over the substrate 112 on the front side 112F, and connecting structures such as metal-to-drain (MD) contacts or metal-to-device (MD) contacts 170 and 172 are formed in the dielectric structures. The MD contacts 170 and 172 are for connecting the doped structures 140, 142, 144 and 146 to a BEOL interconnection, and enable electrical connection between the semiconductor diode structure 110 and the BEOL interconnection. In some embodiments, the MD contacts 170 are coupled to the doped structures 140 and 142 in the first region 114, and the MD contacts 172 are coupled to the doped structures 144 and 146 in the third region 118, as shown in FIG. 7M. However, in some embodiments, the MD contacts 170 are coupled to the doped structures 140 in the first region 114, and the MD contacts 172 are coupled to the doped structures 44 in the third region 118, while the doped structure 142 in the first region 114 is isolated from the MD contacts 170, and the doped structure 146 in the third region 118 is isolated from the MD contacts 172. In such embodiments, top surfaces of the doped structures 142 and 146 may be entirely covered by the dielectric structure 148.

Referring to FIG. 7N, in some embodiments, conductive lines 180m and via connectors 180v are formed over the dielectric structure 148 and coupled to the MD contacts 170 that are coupled to the doped structures 140 in the first region 114, and conductive lines 182m and via connectors 182v are formed over the dielectric structure 148 and coupled to the MD contacts 172 that are coupled to the doped structures 144 in the third region 118. However, in some embodiments, the doped structure 142 in the first region 114 may be isolated from the via connectors 180v and/or the conductive lines 180m, and the doped structure 146 in the third region 118 may be isolated from the via connectors 182v and/or the conductive lines 182m, as shown in FIG. 5. Additionally, in some embodiments, the conductive lines 180m and the conductive lines 182m may extend in the direction D2, but the disclosure is not limited thereto. In some embodiments, the conductive lines 180m and 182m and the via connectors 180v and 182v are formed by BEOL interconnect process and may be referred to as a part of a front-side BEOL interconnect structure.

Still referring to FIG. 7N, in some embodiments, the doped structures 140 and 142 in the first region 114 may be electrically connected to an anode terminal through the MD contacts 170, the via connector 180v and the conductive lines 180m. In such embodiments, the conductive lines 180m may be referred to as anode conductive lines. In such embodiments, the doped structures 140 and 142 in the first region 114 may be referred to as anodes. The doped structures 144 and 146 in the third region 118 may be electrically connected to a cathode terminal through the MD contacts 172, the via connector 182v and the conductive lines 182m. In such embodiments, the conductive lines 182m may be referred to as cathode conductive lines. In such embodiments, the doped structures 144 and 146 in the third region 118 may be referred to as cathodes.

Please refer to FIGS. 70 to 7S, which are schematic cross-sectional views of intermediate semiconductor structures 314 to 318 according to some embodiments corresponding to operation 210. In operation 210, anode conductive lines and cathode conductive lines are formed over the substrate 112 on the back side 112B. In some embodiments, operation 210 includes further operations. For example, referring to FIG. 70, a carrier wafer 184 is bonded to a top surface of the BEOL interconnect structure. The carrier wafer 184 may be bonded to the top surface by one or more bonding layers. The carrier wafer 184 may be a glass carrier substrate, a ceramic carrier substrate, a wafer (e.g., a silicon wafer), or the like. The carrier wafer 184 may provide structural support during subsequent processing steps and in the completed device. In various embodiments, the carrier wafer 184 may be bonded to the BEOL interconnect structure using a suitable technique, such as dielectric-to-dielectric bonding, or the like.

Referring to FIG. 7P, the substrate 112 is flipped over such that the back side 112B may be exposed. Referring to FIG. 7Q, in some embodiments, a portion of the substrate 112 is removed from the back side 112B. In some embodiments, the removal of the portion of the substrate 112 includes thinning the substrate 112 from the back side 112B. In some embodiments, a thinning process may be performed on the back side 112B of the substrate 112. The thinning process may include a planarization process (e.g., a mechanical grinding, a CMP, or the like), an etch-back process, a combination thereof, or the like. With such suitable thinning processes, a thickness of the substrate 112 is reduced. In some embodiments, a thickness T of the thinned substrate 112′ is between approximately 10 nanometers and approximately 100 nanometers, but the disclosure is not limited thereto. In some embodiments, the thinned substrate 112′ may be referred to as a semiconductor layer 112′.

Referring to FIG. 7R, in some embodiments, an insulating layer 186 is formed over the semiconductor layer 112′ on the back side 112B. In some embodiments, the insulating layer 186 includes a single-layered structure or a multi-layered structure. In some embodiments, the insulating layer 186 includes SiN, silicon oxide (SiO), silicon oxynitride (SiON), SiCN, SiOCN, SiCO, or a high-k dielectric material (e.g., HfO, AlO, etc.), but the disclosure is not limited thereto. The insulating layer 186 may serve as a bottom isolation for mitigating a bottom leakage issue.

Referring to FIG. 7S, in some embodiments, backside conductive lines 190m, 192m and bottom via connectors 190v, 192v are formed over the substrate 112′ on the back side 112B. The backside conductive lines 190m and the bottom via connectors 190v are coupled to the doped structures 140 in the first region 114, and the backside conductive lines 192m and the bottom via connectors 192v are coupled to the doped structures 144 in the third region 118. As shown in FIG. 7S, in some embodiments, the bottom via connectors 190v penetrate the insulating layer 186 and the semiconductor layer 112′ from the back side 112B to contact the doped structures 140, and the backside conductive lines 190m are electrically connected to the doped structures 140 through the bottom via connectors 190v. The bottom via connectors 192v penetrate the insulating layer 186 and the semiconductor layer 112′ from the back side 112B to contact the doped structures 144, and the backside conductive lines 192m are electrically connected to the doped structures 144 through the bottom via connectors 192v. Further, the doped structure 142 in the first region 114 is electrically isolated from the bottom via connectors 190v and the backside conductive lines 190m, and the doped structure 146 in the third region 118 is electrically isolated from the bottom via connectors 192v and the backside conductive lines 192m. In some embodiments, the regions where the doped structures 142 and 146 are located are therefore defined as backside via (VB) blocking regions. Additionally, in some embodiments, the backside conductive lines 190m and the backside conductive lines 192m may extend in the direction D1, but the disclosure is not limited thereto. In some embodiments, the backside conductive lines 190m and 192m and the bottom via connectors 190v and 192v are formed by a BEOL interconnect process and may be referred to as a part of a backside BEOL interconnect structure.

Still referring to FIG. 7S, in some embodiments, the doped structures 140 in the first region 114 may be electrically connected to an anode terminal through the bottom via connectors 190v and the backside conductive lines 190m. In such embodiments, the backside conductive lines 190m may be referred to as backside anode conductive lines. The doped structures 144 in the third region 118 may be electrically connected to a cathode terminal through the bottom via connector 192v and the backside conductive lines 192m. In such embodiments, the backside conductive lines 192m may be referred to as backside cathode conductive lines.

Thus, the semiconductor layer 112′ allows standard GAA processing of the device and facilitates provision of the backside interconnect structure, which may include the back side power delivery network. Further, the nanostructure channels 122 in the first region 114 and the third region 118 and a portion of the semiconductor layer 112′ in the second region 116 function as a conducting path of the semiconductor diode structure 110. As such, a path length for conducting current resulting from an ESD event is increased, thereby improving the ESD protection result.

In some comparative approaches, when the thickness T of the semiconductor layer 112′ is less than 10 nanometers, a resistance is increased and thus adverse impact is generated on a current passing through the semiconductor layer 112′. In some comparative approaches, when the thickness T of the semiconductor layer 112′ is greater than 10 nanometers, a resistance of the bottom via connectors 190v and 192v is increased and thus adverse impact is generated on the current passing through the bottom via connectors 190v and 192v.

Accordingly, the present disclosure provides a semiconductor diode structure and a method for forming the same. In some embodiments, the provided semiconductor diode structure is integrated into an SPR structure for efficiently providing power to operational components of an IC. In contrast to previous power rail structures that only provide power from one side of a substrate, the SPR structure of the present disclosure allows power to be provided from a front side and a back side of a substrate incorporating the SPR structure. In some embodiments, the semiconductor diode structure includes a semiconductor layer that serves as a current path to bias the ESD in the bulk-less process, which allows for processes such as dual-side power rails.

According to one embodiment of the present disclosure, a semiconductor diode structure is provided. The semiconductor diode structure includes a semiconductor layer, a first p-type doped structure disposed over the semiconductor layer, a first n-type doped structure disposed over the semiconductor layer, a central structure disposed between the first p-type doped structure and the first n-type doped structure, a second p-type doped structure disposed between the first p-type doped structure and the central structure, and a second n-type doped structure disposed between the first n-type doped structure and the central structure. The first and second p-type doped structures are line symmetric to the first and second n-type doped structure about the central structure.

According to one embodiment of the present disclosure, a method for forming a semiconductor structure is provided. The method includes the following operations. A plurality of sacrificial gates are formed over a front side of a substrate. Each of the sacrificial gates covers a nanostructure stack. The sacrificial gates are separated from each other by a recess. The recesses are filled with a first insulating structure, a second insulating structure and a third insulating structure. A first doped structure is formed to replace the first insulating structure. A second doped structure is formed to replace the second insulating structure. Dopants in the first doped structure and dopants in the second doped structure are complementary. An isolation is formed to replace the third insulating structure. The sacrificial gates are replaced with metal gates. A first bottom via connector coupled to the first doped structure and a second bottom via connector coupled to the second doped structure are formed. The first bottom via connector and the second bottom via connector penetrate the substrate from a back side.

According to one embodiment of the present disclosure, a method for forming a semiconductor structure is provided. The method includes the following operations. A substrate is received. The substrate includes a first region, a second region and a third region defined therein. The second region is defined between the first region and the third region. A nanostructure stack is formed over the substrate. A plurality of sacrificial gates is formed over the nanostructure stack. Portions of the nanostructure stack are removed to form a plurality of recesses in the first region, the second region and the third region. A first doped structure and a second doped structure are formed in the recesses in the first region. A third doped structure and fourth doped structure are formed in the recesses in the third region. A plurality of isolations is formed in the recesses in the second region. The sacrificial gates are replaced with metal gates. A plurality of anode conductive lines are formed on a front side of the substrate. The anode conductive lines are coupled to the first doped structure and the second doped structure. A plurality of cathode conductive lines is formed on the front side of the substrate. The cathode conductive lines are coupled to the third doped structure and the fourth doped structure. A portion of the substrate is removed from a back side of the substrate. At least a backside anode conductive line and at least a backside cathode line are formed over the substrate on the back side. The backside anode conductive line is coupled to the first doped structure in the first region, and the backside cathode conductive line is coupled to the third doped structure in the third region.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor diode structure comprising:
a semiconductor layer;
a first p-type doped structure over the semiconductor layer;
a first n-type doped structure over the semiconductor layer;
a central structure between the first p-type doped structure and the first n-type doped structure;
a second p-type doped structure between the first p-type doped structure and the central structure; and
a second n-type doped structure between the first n-type doped structure and the central structure,
wherein the first and second p-type doped structures are line symmetric to the second and first n-type doped structures about the central structure.

2. The semiconductor diode structure of claim 1, further comprising:
a plurality of first nanostructure channels between the first p-type doped structure and the second p-type doped structure;
a first gate structure wrapping around each of the first nanostructure channels;
a plurality of second nanostructure channels between the first n-type doped structure and the second n-type doped structure; and
a second gate structure wrapping around each of the second nanostructure channels.

3. The semiconductor diode structure of claim 1, wherein the central structure comprises:
a plurality of third nanostructure channels;
a third gate structure wrapping around each of the third nanostructure channels; and
a pair of isolations,
wherein the third nanostructure channels and the third gate structure are between the pair of isolations.

4. The semiconductor diode structure of claim 1, further comprising:
a plurality of fourth nanostructure channels between the second p-type doped structure and the central structure;
a fourth gate structure wrapping around each of the fourth nanostructure channels;
a plurality of fifth nanostructure channels disposed between the second n-type doped structure and the central structure; and
a fifth gate structure wrapping around each of the fifth nanostructure channels.

5. The semiconductor diode structure of claim 1, further comprising:
a first bottom via connector coupled to the first p-type doped structure; and
a second bottom via connector coupled to the first n-type doped structure.

6. The semiconductor diode structure of claim 5, wherein the second p-type doped structure is isolated from the first bottom via connector, and the second n-type doped structure is isolated from the second bottom via connector.

7. The semiconductor diode structure of claim 1, further comprising an insulating layer, wherein the insulating layer is on a side of the semiconductor layer opposite to the central structure.

8. The semiconductor diode structure of claim 1, further comprising:
a first front via connector coupled to the first p-type doped structure; and
a second front via connector coupled to the first n-type doped structure.

9. The semiconductor diode structure of claim 8, further comprising:
a third front via connector coupled to the second p-type doped structure; and
a fourth front via connector coupled to the second n-type doped structure.

10. A method for forming a semiconductor structure, comprising:
forming a plurality of sacrificial gates over a front side of a substrate, wherein each of the sacrificial gates covers a nanostructure stack, and the sacrificial gates are separated from each other by a recess;
filing the recesses with a first insulating structure, a second insulating structure and a third insulating structure;
forming a first doped structure to replace the first insulating structure;
forming a second doped structure to replace the second insulating structure, wherein dopants in the first doped structure and dopants in the second doped structure are complementary;
forming an isolation to replace the third insulating structure;
replacing the sacrificial gates with metal gates; and
forming a first bottom via connector coupled to the first doped structure and a second bottom via connector coupled to the second doped structure, wherein the first bottom via connector and the second bottom via connector penetrate the substrate from a back side of the substrate.

11. The method of claim 10, further comprising thinning the substrate.

12. The method of claim 10, further comprising forming an anode conductive line coupled to the first bottom via connector and forming a cathode conductive line coupled to the second bottom via connector on the back side of the substrate.

13. The method of claim 10, further comprising:
forming a third doped structure between the first doped structure and the isolation, wherein the third doped structure comprises dopants same as the dopants of the first doped structure; and
forming a fourth doped structure between the second doped structure and the isolation, wherein the fourth doped structure comprises dopants same as the dopants of the second doped structure.

14. The method of claim 13, wherein forming the third doped structure comprises forming the third doped structure and the fourth doped structure isolated from the first bottom via connector and the second bottom via connector.

15. The method of claim 13, wherein forming the first doped structure comprise forming the first doped structure, the second doped structure, the third doped structure and the fourth doped structure simultaneously.

16. A method for forming a semiconductor structure, comprising:
forming a nanostructure stack over a substrate, wherein the substrate has a first region, a second region and a third region therein, wherein the second region is between the first region and the third region;
forming a plurality of sacrificial gates over the nanostructure stack;
removing portions of the nanostructure stack to form a plurality of recesses in the first region, the second region and the third region;
forming a first doped structure and a second doped structure in the recesses in the first region;
forming a third doped structure and a fourth doped structure in the recesses in the third region;
forming a plurality of isolations in the recesses in the second region;
replacing the sacrificial gates with metal gates;
forming a plurality of anode conductive lines coupled to the first doped structure and the second doped structure in the first region on a front side of the substrate;
forming a plurality of cathode conductive lines coupled to the third doped structure and the fourth doped structure in the third region on the front side of the substrate;
removing a portion of the substrate from a back side of the substrate; and
forming at least a backside anode conductive line coupled to the first doped structure in the first region and at least a backside cathode conductive line coupled to the third doped structure in the third region on the back side of the substrate.

17. The method of claim 16, wherein forming the second doped structure comprises forming the second doped structure isolated from the backside anode conductive line, and forming the fourth doped structure comprises forming the fourth doped structure isolated from the backside cathode conductive line.

18. The method of claim 16, further comprising forming an insulating layer on the back side of the substrate after the removing of the portion of the substrate.

19. The method of claim 18, further comprising forming a plurality of bottom via connectors and penetrating the insulating layer and the substrate.

20. The method of claim 16, wherein forming the second doped structure comprises forming the second doped structure between the isolations and the first doped structure, and forming the fourth doped structure comprises forming the fourth doped structure between the isolations and the third doped structure.
